(19) United States
(12) Patent Application Publication
(10) Pub. No.: US 2020/0111773 A1
(43) Pub. Date: Apr. 9, 2020

(54) INTEGRATED CIRCUIT (IC) PACKAGE WITH HETROGENOUS IC CHIP INTERPOSER

(71) Applicant: International Business Machines Corporation, Armonk, NY (US)

(72) Inventors: Arvind Kumar, Chappaqua, NY (US); Joshua M. Rubin, Albany, NY (US)

(21) Appl. No.: 16/155,174

(22) Filed: Oct. 9, 2018

(51) Int. Cl. H01L 25/18; H01L 23/538; H01L 23/10; H01L 23/31; H01L 25/00; H01L 23/498; H01L 23/00

(52) U.S. Cl. CPC H01L 25/18; H01L 23/5386; H01L 23/10; H01L 23/3121; H01L 2924/1434; H01L 23/49838; H01L 24/81; H01L 24/17; H01L 2924/1433; H01L 25/50

(57) ABSTRACT

An interposer is electrically connected to heterogenous IC chips. A first IC chip is electrically connected to a first IC chip facing surface of the interposer. One or more second IC chips are electrically connected to a carrier facing surface of the interposer. The interposer may be electrically connected to a carrier which includes one or more topographic features that provide clearance for a respective second IC chip. Power and/or ground potential may be provided by or though the carrier to the one or more second IC chips and to the first IC chip by way of the interposer. An access instruction to pass data to the second IC chip or to obtain data from the second IC chip may be provided by the first IC chip to the one or more second IC chips by way of the interposer.

### FIELD

Embodiments of invention generally relate to semiconductor chip packaging. More particularly, embodiments relate to an integrated circuit (IC) chip package that includes an interposer that which electrically connects to heterogenous IC chips.

### BACKGROUND

There is a need to place heterogenous IC chips, such as a processor, application specific integrated circuit (ASIC), and/or memory chip, close to one another to be electrically connected by relatively short wiring.

### SUMMARY

In an embodiment of the present invention, a method of integrated circuit (IC) package fabrication is presented. The method includes joining a first IC chip to a chip facing surface of a heterogeneous IC chip interposer. The method includes joining a second IC chip to a carrier facing surface of the heterogeneous IC chip interposer. The carrier facing surface opposes the chip facing surface. The method includes, after joining the second IC chip to the heterogenous IC chip interposer, positioning IC chip within a topographic recess of a carrier and positioning the heterogeneous IC chip interposer between the first IC chip and the carrier. The method further includes joining the carrier facing surface of the heterogenous IC chip interposer with the carrier.

In another embodiment of the present invention, an integrated circuit (IC) package is presented. The package includes a first IC chip joined to a first IC chip facing surface of an heterogenous IC chip interposer and a second IC chip joined to a carrier facing surface of the heterogeneous IC chip interposer. The carrier facing surface opposes the processing chip facing surface. The package further includes a carrier that includes a topographic recess. The carrier is joined to the carrier facing surface of the heterogeneous IC chip interposer. The heterogenous IC chip interposer is between the first IC chip and the carrier. The second IC chip is within a topographic recess of the carrier.

In another embodiment of the present invention, an electronic system is presented. The system includes a first IC chip joined to a first IC chip facing surface of an heterogenous IC chip interposer and a second IC chip joined to a carrier facing surface of the heterogeneous IC chip interposer. The carrier facing surface opposes the processing chip facing surface. The system further includes a carrier that includes a topographic recess. The carrier is joined to the carrier facing surface of the heterogeneous IC chip interposer. The heterogenous IC chip interposer is between the first IC chip and the carrier. The second IC chip is within a topographic recess of the carrier.

These and other embodiments, features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts views of an exemplary IC package carrier, in accordance with one or more embodiments of the present invention.

FIG. 2 depicts views of an exemplary IC chip, in accordance with one or more embodiments of the present invention.

FIG. 3 depicts views of an exemplary heterogenous IC chip interposer, in accordance with one or more embodiments of the present invention.

FIG. 4 depicts a cross section view of an exemplary IC chip interposer fabrication stage, in accordance with one or more embodiments of the present invention.

FIG. 5 depicts a cross section view of an exemplary IC package fabrication stage, in accordance with one or more embodiments of the present invention.

FIG. 6 depicts a view of an exemplary IC processing chip, in accordance with one or more embodiments of the present invention.

FIG. 7 depicts a cross section view of an exemplary IC package fabrication stage, in accordance with one or more embodiments of the present invention.

FIG. 8 depicts a cross section view of an exemplary IC package, in accordance with one or more embodiments of the present invention.

FIG. 9 depicts a detailed cross section view of an exemplary IC package, in accordance with one or more embodiments of the present invention.

FIG. 10A and FIG. 10B depict a cross section view of an exemplary IC package fabrication stage, in accordance with one or more embodiments of the present invention.

FIG. 11 depicts a view of an exemplary IC processing chip, in accordance with one or more embodiments of the present invention.

FIG. 12 depicts a cross section view of an exemplary IC package fabrication stage, in accordance with one or more embodiments of the present invention.

FIG. 13 depicts a cross section view of an exemplary IC package, in accordance with one or more embodiments of the present invention.

FIG. 14 depicts a detailed cross section view of an exemplary IC package, in accordance with one or more embodiments of the present invention.

FIG. 15 depicts a detailed cross section view of an exemplary IC package, in accordance with one or more embodiments of the present invention.

FIG. 16A and FIG. 16B depict a cross section view of an exemplary IC package fabrication stage, in accordance with one or more embodiments of the present invention.

FIG. 17 depicts a cross section view of an exemplary IC package fabrication stage, in accordance with one or more embodiments of the present invention.

FIG. 18 depicts a view of an exemplary IC chip, in accordance with one or more embodiments of the present invention.

FIG. 19 depicts a cross section view of an exemplary IC package, in accordance with one or more embodiments of the present invention.

FIG. 20 depicts a detailed cross section view of an exemplary IC package, in accordance with one or more embodiments of the present invention.

FIG. 21A and FIG. 21B depict a cross section view of an exemplary IC package fabrication stage, in accordance with one or more embodiments of the present invention.

FIG. 22 depicts a cross section view of an exemplary IC package fabrication stage, in accordance with one or more embodiments of the present invention.

FIG. 23 depicts a view of an exemplary IC chip, in accordance with one or more embodiments of the present invention.

FIG. 24 depicts views of an exemplary IC package carrier, in accordance with one or more embodiments of the present invention.

FIG. 25 depicts a cross section view of an exemplary IC package, in accordance with one or more embodiments of the present invention.

FIG. 26 depicts a detailed cross section view of an exemplary IC package, in accordance with one or more embodiments of the present invention.

FIG. 27 depicts a cross section view of an exemplary IC package fabrication stage, in accordance with one or more embodiments of the present invention.

FIG. 28 depicts a cross section view of an exemplary IC package fabrication stage, in accordance with one or more embodiments of the present invention.

FIG. 29 depicts a cross section view of an exemplary IC package, in accordance with one or more embodiments of the present invention.

FIG. 30 depicts a detailed cross section view of an exemplary IC package, in accordance with one or more embodiments of the present invention.

FIG. 31A and FIG. 31B depict a cross section view of an exemplary IC package fabrication stage, in accordance with one or more embodiments of the present invention.

FIG. 32 depicts a cross section view of an exemplary IC package fabrication stage, in accordance with one or more embodiments of the present invention.

FIG. 33 depicts a cross section view of an exemplary IC package, in accordance with one or more embodiments of the present invention.

FIG. 34 depicts a detailed cross section view of an exemplary IC package, in accordance with one or more embodiments of the present invention.

FIG. 35 depicts an exemplary IC package fabrication method, in accordance with one or more embodiments of the present invention.

FIG. 36 depicts an exemplary method of accessing, powering, and/or grounding a memory an IC package, in accordance with one or more embodiments of the present invention.

FIG. 37 depicts an exemplary IC package fabrication method, in accordance with one or more embodiments of the present invention.

The drawings are not necessarily to scale. The drawings are merely schematic representations, not intended to portray specific parameters of the invention. The drawings are intended to depict only exemplary embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Embodiments of invention relate to an interposer that is electrically connected to heterogenous IC chips. A first IC chip is electrically connected to a first IC chip facing surface of the interposer. One or more second IC chips are electrically connected to a carrier facing surface of the interposer. The interposer may be electrically connected to a carrier which includes one or more topographic features that provide clearance for a respective second IC chip. Power and/or ground potential may be provided by or though the carrier to the one or more second IC chips and to the first IC chip by way of the interposer. An access instruction to pass data to the second IC chip or to obtain data from the second IC chip may be provided by the first IC chip to the one or more second IC chips by way of the interposer.

Referring now to the figures, wherein like components are labeled with like numerals, exemplary structures of a semiconductor device, in accordance with embodiments of the present invention are shown and will now be described in greater detail below. The specific number of components depicted in the figures and the cross-section orientation was chosen to best illustrate the various embodiments described herein.

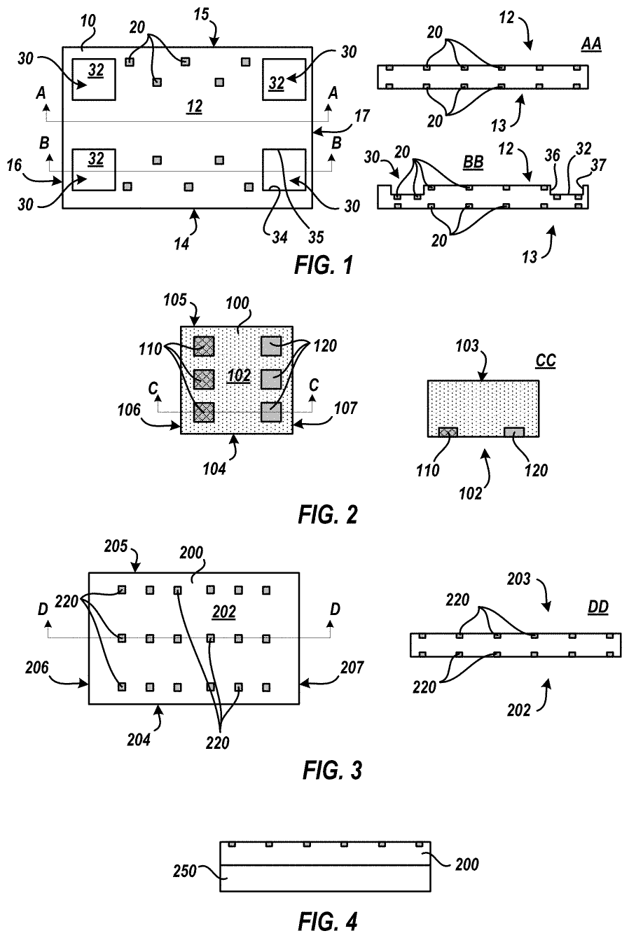

FIG. 1 depicts views of an exemplary IC package carrier 10, in accordance with one or more embodiments of the present invention.

Carrier 10 is configured to electrically attach to an interposer by way of carrier contacts 20 on or in chip facing surface 12. Carrier 10 is also configured to electrically attach to a system, such as a mother board, system board, or the like on system facing surface 13 by way of carrier contacts 20 thereupon or therein. A carrier contact 20 of surface 12 is electrically connected to a carrier contact 20 of surface 13 by an electrical pathway as is known in the art. Carrier 10 may also have a front surface 14, rear surface 15, side surface 16, and side surface 17.

Carrier 10 includes one or more topographic features 30 that provide clearance for a respective an IC chip. As depicted, topographic feature 30 extends internally into carrier 10 and may be a recess, void, cutout, or the like. Topographic feature 30 includes a chip facing surface 32 that is recessed internally from chip facing surface 12. Topographic feature 30 may also have a front surface 34, rear surface 35, side surface 36, and side surface 37. One or more carrier contacts 20 may be included upon or within chip facing surface 32 of topographic feature 30.

Carrier 10 may be a flip chip carrier, also known as controlled collapse chip connection or C4 carrier. In some embodiments, the carrier 10 is fabricated from at least in part organic laminate materials or layers.

FIG. 2 depicts views of an exemplary IC chip 100 in accordance with one or more embodiments of the present invention. IC chip 100 is a device that may stores data and/or process data. In embodiments, IC chip 100 may be high bandwidth memory (HBM) device, a dynamic random-access memory (DRAM) device, static random-access memory (SRAM) device, or a solid-state memory, such as a Flash memory device. In some embodiments, IC chip 100 may be a processor. In some embodiments, IC chip 100 may be a field programmable gate array IC chip. In some embodiments, IC chip 100 may be a logic IC chip.

IC chip 100 includes contacts that allow for other electronic devices to electrically connect thereto. More specifically, IC chip 100 includes one or more power and/or ground contacts 120 and one or more input/output (I/O) contacts 110. The power contact(s) 120 is electrically connected to a potential distribution circuit system within IC chip 100. The ground contact(s) 120 are connected to a ground distribution circuit system within IC chip 100. The I/O contact(s) 110 are utilized to receive I/O data from an interconnected other device or are utilized to convey I/O data to an interconnected other device. Each of the contacts 110, 120 may be located on a same contact surface 102 of memory 120. IC chip 100 may also have a front surface 104, rear surface 105, side surface 106, and side surface 107.

FIG. 3 depicts views of an exemplary heterogenous IC chip interposer 200, in accordance with one or more embodiments of the present invention. Interposer 200 is configured to electrically attach to the processing IC chip and IC chip 100 on chip facing surface 202 by way of interposer contacts 220 thereupon or therein. Interposer 200 is also configured to electrically attach to carrier 10 on carrier facing surface 203 by way of interposer contacts 220 thereupon or therein. An interposer contact 220 of surface 202 is electrically connected to a interposer contact 220 of surface 203 by an electrical pathway as is known in the art. Interposer 200 may also have a front surface 204, rear surface 205, side surface 206, and side surface 207. Contacts 220 are generally conductive structures upon or within the interposer, such as pads, bumps or like.

Heterogenous IC chip interposer 200 is configured to be located between carrier 10 and a processing IC chip. As such, the thickness of heterogenous IC chip interposer 200 (i.e., distance between surface 202 and 203) may be minimized. Similarly, interposer 200 may be absent of any single through interposer 200 electrical pathway feature, such as a through via, that extend from surface 202 to 203.

FIG. 4 depicts a cross section view of an exemplary heterogenous IC chip interposer 200 fabrication stage, in accordance with one or more embodiments of the present invention. Heterogenous IC chip interposer 200 may be fabricated by forming a buildup of dielectric and wiring levels upon a handle 250 that may be a glass or silicon wafer format, or in panel format, as is used in the fanout panel level packaging. Contacts 220 may be formed upon buildup of dielectric and wiring layers and may be connected to one or more wires within interposer 200, respectively.

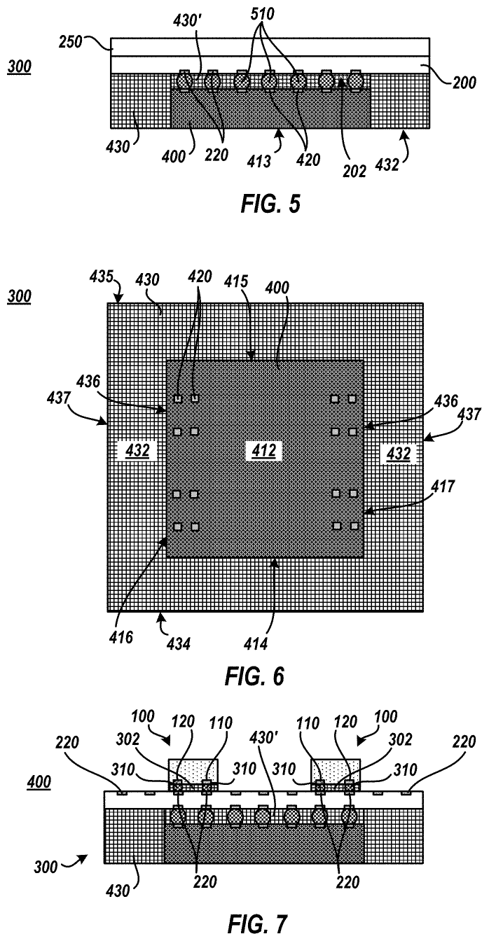

FIG. 5 depicts a cross section view of an exemplary IC package 300 fabrication stage, in accordance with one or more embodiments of the present invention. IC package 300 includes handle 250, interposer 200, and one or more IC processing chips 400. IC processing chip 400 is an IC chip that processes data, such a processor, ASIC, field programmable gate array (FPGA), or the like. Chip 400 includes processing chip contacts 420 on or in contact surface 412 that are configured to electrically attach to contacts 220 on or in chip facing surface 202 of interposer 200.

The processing chip 400 may be electrically connected to interposer 200 of package 300 by connecting respective contacts 420 and respective contacts 220 on or in chip facing surface 202 of interposer 200 with respective processing-chip-interposer interconnects 510. Processing-chip-interposer interconnect 510 may be solder, C4 solder, micro solder, buttons, posts, pins, or the like, that are electrically conductive to allow current to flow between a contact 420 and a contact 220. In some implementations, processing-chip-interposer interconnect 510 is a larger interconnect relative to IC-chip-interposer interconnect 310. For example, a diameter of the IC-chip-interposer interconnect 310 may be on the micrometer bump scale (e.g., 50 micrometers, etc.) while a diameter of the processing-chip-interposer interconnect 510 may be a larger C4 bump scale (e.g., 150 micrometers, etc.).

In some implementations, IC package 300 may further include one or more fillers. Filler may be mold material 430, underfill material 430′, or the like, and may be formed around the circumference of IC processing chip(s) 410, between the interposer 200 and IC processing chip(s) 400 surrounding respective interconnects 510.

FIG. 6 depicts a view of IC processing chip 400, in accordance with one or more embodiments of the present invention. Chip 400 may also have a top surface 413, front surface 414, rear surface 415, side surface 416, and side surface 417.

In some embodiments, a filler 430 may be connected to chip 400. Filler 430 generally fills space within the IC package and may be for example, mold material, or the like. Filler 430 may have a interposer facing surface 432, a top surface 433, front surface 434, rear surface 435, side surface 436, and side surface 437. Top surface 433 of filler 430 may be coplanar with top surface 413 of chip 400, and the like.

FIG. 7 depicts a cross section view of an exemplary IC package 500 fabrication stage, in accordance with one or more embodiments of the present invention. IC package 500 includes IC processing chip 400, interposer 200, and one or more IC chips 100. IC package 500 may be formed by removing handle 250 from interposer 200. Contacts 220 may be formed upon carrier facing surface 203 of interposer 200. Such contacts 220 may connected to one or more wires located within interposer 200. As such, electrical pathways may be formed from carrier facing surface 203 to chip facing surface 202 of interposer 200 via contacts 220 and internally formed wires.

The IC chip(s) 100 may each be electrically connected to interposer 200 by connecting a power contact 120 and a first interposer contact 220 upon surface 203 with a first IC-chip-interposer interconnect 310, by connecting a ground contact 120 and a second interposer contact 220 upon surface 203 with a second IC-chip-interposer interconnect 310, and/or by connecting a I/O contact 110 and a third interposer contact 220 upon surface 203 with a third IC-chip-interposer interconnect 310.

IC-chip-interposer interconnect 310 may be solder, C4 solder, micro solder, buttons, posts, pins, or the like, that are electrically conductive to allow current to flow between a contact 110, 120 of contact surface 102 and a contact 120 of carrier facing surface 203.

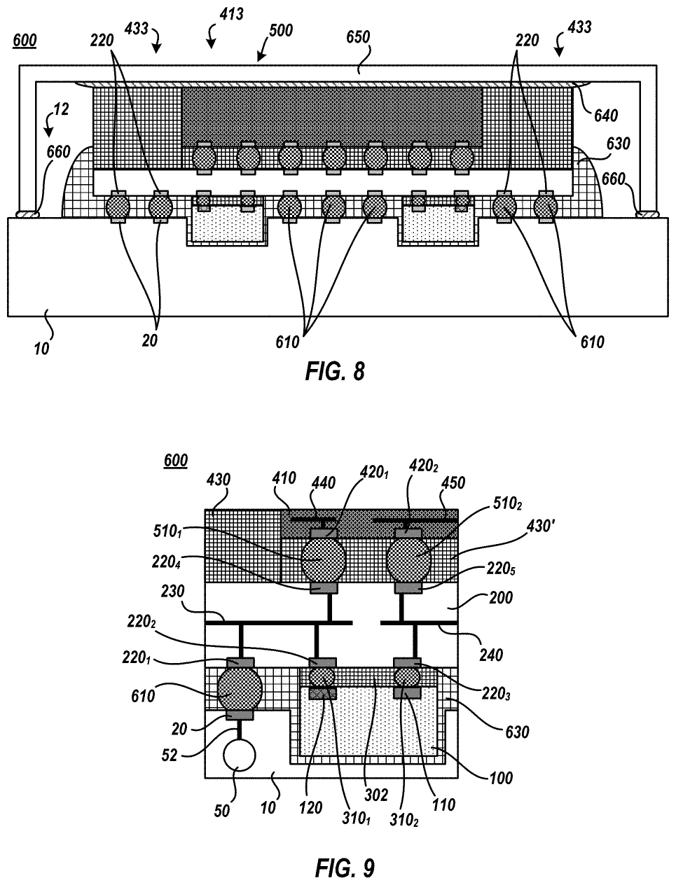

The one or more IC chips 100 may be located upon the contacts 220 of surface 203 interposer 200 such that the respective IC chips 100 may be positioned within a topographic feature 30, upon when other contacts 220 of surface 203 of the interposer 200 are electrically connected to respective contacts 20 of carrier 10, as exemplarily depicted in FIG. 8.

Underfill 302 may be included within IC package 500. Underfill 302 is electrically-insulating and may substantially surround interconnects 310, may electrically isolate individual interconnects 310, and may provide mechanical support between package IC chip 100 and interposer 200. Underfill 302 may also prevent damage to individual interconnects 310 due to thermal expansion mismatches between interposer 200 and IC chip 100. For clarity, underfill 302 may exist between the IC chip 100 and interposer 200 surrounding interconnects 310. Underfill 302 may be pre-applied before joining the IC chips to interposer 200 or applied after join using capillary underfill.

In some implementations, interconnects 510, 310 on either side of interposer 200 may be of different types and/or different dimensional scales.

FIG. 8 depicts a cross section view of an exemplary IC package 600, in accordance with one or more embodiments of the present invention. IC package 600 includes package 500 and at least carrier 10. IC package 600 may further include underfill 630, thermal interface 640, cover 650, and/or seal band 660.

The interposer 200 may be electrically connected to carrier 10 by connecting respective carrier contacts 20 and respective contacts 220 on or in carrier facing surface 203 of interposer 200 with respective carrier-interposer interconnects 610. Carrier-interposer interconnect 610 may be solder, C4 solder, micro solder, buttons, posts, pins, or the like, that are electrically conductive to allow current to flow between a contact 20 and a contact 220. In some implementations, processing-chip-interposer interconnect 610 is the same type of interconnect as processing-chip-interposer interconnect 510. In some implementations, processing-chip-interposer interconnect 610 is a larger interconnect relative to IC-chip-interposer interconnect 310.

IC package 500 may be positioned relative to carrier 10 such that at least IC chip 100 is located within an associated topographic feature 30 of carrier 10 upon when contacts 220 of surface 203 of the interposer 200 are electrically connected to respective contacts 20 of carrier 10 by processing-chip-interposer interconnect 610. In other words, carrier surface 102 is between the chip facing surface 12 of carrier 10 and chip facing surface 32 of topographic feature 30. As such, the shape of topographic feature 30 may be dictated by the perimeter shape of the IC chip 100 for which it provides clearance. For example, when the interposer 200 is attached to the carrier 10, a clearance may be provided between chip facing surface 32, front surface 34, rear surface 35, side surface 36, and side surface 37 of the topographic feature 30 and associated carrier facing surface 103, front surface 104, rear surface 105, side surface 106, and side surface 107 of the IC chip 100.

Underfill 630 may be included within IC package 600 and is electrically-insulating, may substantially surround interconnects 610, may electrically isolate individual interconnects 610, and may provide mechanical support between package 500 and carrier 10. As such, underfill 630 may generally surround package 500 between contact surface 412 of processing chip 400 & surface 433 of filler 420 and contact surface 12 of carrier 10. Underfill 630 may also prevent damage to individual interconnects 610 due to thermal expansion mismatches between carrier 10, interposer 200, and processing chip 400. For clarity, underfill 630 may exists within the clearance between IC chip 100 and the associated topographic feature 30 of carrier 10. In some embodiments, underfill 630 may include a distinct material, adhesive, or the like within the topographic feature 32 to connect IC chip 100 to carrier 10.

Cover 650 may be attached to carrier 10 with seal band 660 to cover, encapsulate, etc. processing chip 400. Generally, during operation of processing chip 400, heat needs to be removed from processing chip 400. In this situation, cover 650 is both a cover and a conduit for heat transfer. As such, thermal interface material 640 may thermally connect the underside surface of cover 650 and the upper surface 413 of processing chip 400 and/or the upper surface 433 of filler 430.

As is shown, IC chip(s) 100 are under the footprint of processing IC chip 400. However, for clarity, IC chip(s) 100 need not be under the footprint of the IC chip 400. For example, IC chip(s) can be fully outside, partially outside, etc. the footprint of processing IC chip 400.

FIG. 9 depicts a detailed cross section view of IC package 600, in accordance with one or more embodiments of the present invention. IC chip 100 is electrically connected to interposer 200 by interconnect 310₁ which is connected to power contact 120 of IC chip 100 and contact 220₂ of interposer 200 and by interconnect 310₂ which is connected to IO contact 110 of IC chip 100 and contact 220₃ of interposer 200. Underfill 302 is between IC chip 100 and interposer 200.

Processing IC chip 400 is electrically connected to interposer 200 by interconnect 510₁ which is connected to contact 420₁ of processing IC chip 400 and contact 220₄ of interposer 200 and by interconnect 510₂ which is connected to 420₂ of processing IC chip 400 and contact 220₅ of interposer 200. Processing IC chip 400 may include an electrical path 440 which is electrically connected to contact 420₁ and may include an electrical path 450 which is electrically connected to contact 420₂. Path 440, 450 may include various wiring line features as are known in the art

Carrier 10 is electrically connected to interposer 200 by interconnect 610 which is connected to contact 20 of carrier 10 and contact 220₁ of interposer 200. Carrier 10 may include electrical path 52. Path 52 may include various wiring line features, as are known in the art, and is electrically connected to contact 20. Path 52 is electrically connected to an electrical potential or current source 50 or a ground 50, herein referred to as source/ground 50. Source/ground 50 may be local to carrier 10 or may be local to the system board or mother board electrically connected to the carrier 10.

Interposer 200 may include electrical path 230 and electrical path 240. Path 230, 240 may include various wiring line features as are known in the art. Path 230 may be electrically connected to contact 220₁, to contact 220₂, and to contact 220₄. Path 240 may be electrically connected to contact 220₃ and to contact 220₅.

To obtain data from the IC chip 100, IC processing chip 400 may send a obtain access instruction or signal by way of path 450 to contact 420₂. The obtain access instruction or signal passes through interposer 200 by path 240 and is received by IC chip 100 at contact 110. In turn, IC chip 100 provides the applicable requested data to IC processing chip 400 by the same or different electrical path that which was used by IC chip 100 to receive the obtain access instruction. To pass data to the IC chip 100, IC processing chip 400 may send a pass access instruction or signal by way of path 450 to contact 420₂. The pass access instruction or signal passes through interposer 200 by path 240 and is received by IC chip 100 at contact 110. In turn, IC chip 100 caches or stores the data included in the pass access instruction there within. Similarly, source/ground 50 may provide electrical potential or ground, respectively, to IC chip 100 and/or IC processing chip 400 by way of path 230.

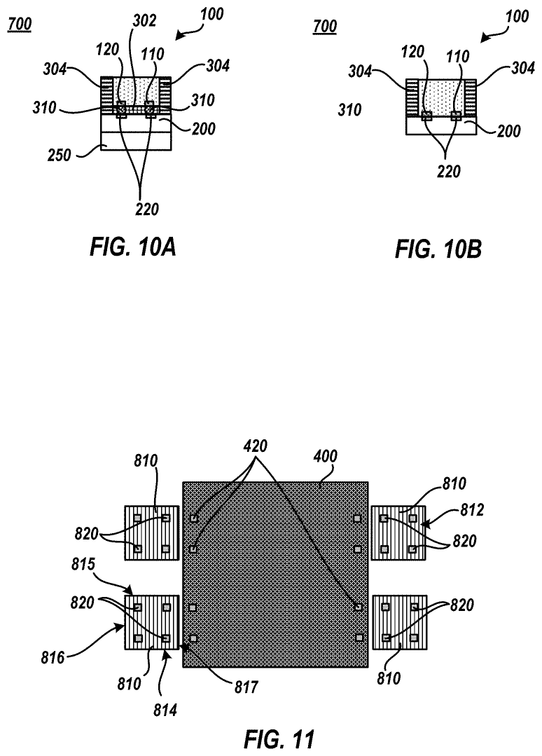

FIG. 10A and FIG. 10B depict a cross section view of an exemplary IC package 700 fabrication stage, in accordance with one or more embodiments of the present invention. FIG. 10A depicts an implementation wherein IC chip 100 is connected to interposer 200 by interconnects 310 and FIG. 10B depicts and implementation wherein interposer 200 is formed upon IC chip 100. IC package 700 includes handle 250, interposer 200, and IC chip 100.

In the present fabrication stage, interposer 200 is formed upon handle 250. Subsequently, IC chip 100 may be connected to interposer 200, as shown in FIG. 10A or interposer 200 may be formed upon IC chip 100, as shown in FIG. 10B.

As shown in FIG. 10A, each IC chip 100 may be electrically connected to an interposer 200 by connecting a power contact 120 and a first interposer contact 220 upon surface 203 with a first IC-chip-interposer interconnect 310, by connecting a ground contact 120 and a second interposer contact 220 upon surface 203 with a second IC-chip-interposer interconnect 310, and/or by connecting a I/O contact 110 and a third interposer contact 220 upon surface 203 with a third IC-chip-interposer interconnect 310. As shown in FIG. 10B, each IC chip 100 may be electrically connected to an interposer 200 by directly connecting a power contact 120 and a first interposer contact 220 upon surface 203, by directly connecting a ground contact 120 and a second interposer contact 220 upon surface 203, and/or by directly connecting a I/O contact 110 and a third interposer contact 220 upon surface 203.

IC package 700 may further include underfill 302 between IC chip 100 and interposer 200. Underfill 302 is electrically-insulating and may substantially surround interconnects 310, may electrically isolate individual interconnects 310, and may provide mechanical support between package IC chip 100 and interposer 200. Underfill 302 may also prevent damage to individual interconnects 310 due to thermal expansion mismatches between interposer 200 and IC chip 100.

IC package 700 may further include mold 304 material formed around the circumference of IC chip 100 and upon interposer 200. The side surfaces of mold 304 may be coplanar with the side surface of interposer 200. The front and rear surfaces of mold 304 may be coplanar with respective front and rear surfaces of interposer 200.

FIG. 11 depicts a view of IC processing chip 400 and power IC chips 810, in accordance with one or more embodiments of the present invention. The IC processing chip 400 may be independent from the power IC chips 810, as exemplarily depicted. In alternative implementations a filler, e.g., mold material, dummy silicon, or the like, may adjacent to IC processing chip 400 and/or power IC chips 810 and act as a gap filler to reduce the tendency of subsequent package warpage. Particular rows of contacts 420 of IC processing chip 400 may be aligned with respective rows of contacts 820 of power IC chip(s) 810.

IC power chip 810 is an IC chip, substrate, or the like, that provides power (e.g. current or potential) and/or ground potential to another discrete IC chip. Chip 810 includes processing chip contacts 820 on or in contact surface 812 that are configured to electrically attach to contacts 220 on or in chip facing surface 202 of interposer 200. Chip 800 may also have a top surface 813, front surface 814, rear surface 815, side surface 816, and side surface 817. Top surface 813 may be coplanar with top surface 433 of chip 400, contact surface 812 may be coplanar with contact surface 412 of chip 400, and the like.

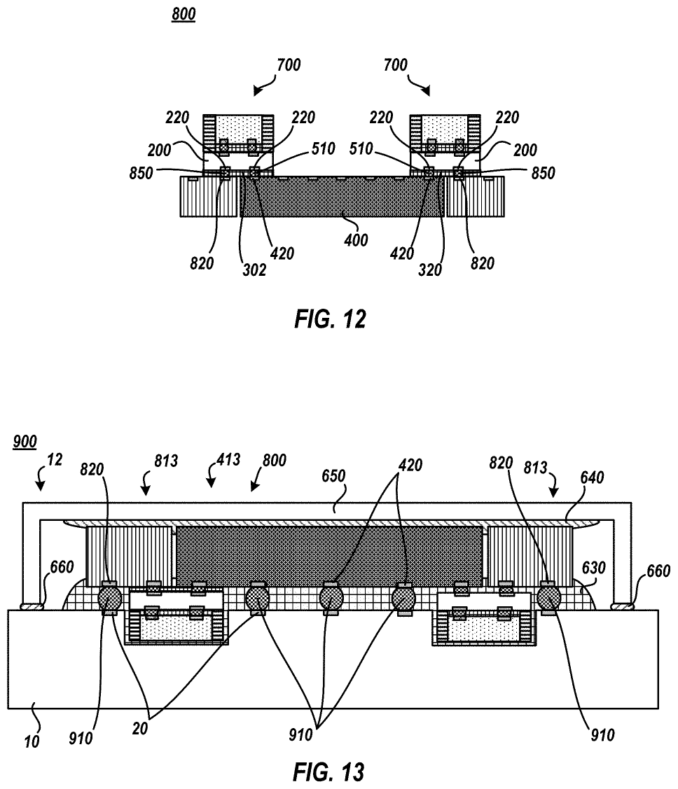

FIG. 12 depicts a cross section view of an exemplary IC package 800 fabrication stage, in accordance with one or more embodiments of the present invention. IC package 800 includes IC processing chip 400, interposer 200, IC chips 100, and power IC chips 810. IC package 800 may be formed by removing handle 250. Contacts 220 may be formed upon carrier facing surface 203 of each interposer 200. Such contacts 220 may connected to one or more wires located within the respective interposer 200. As such, electrical pathways may be formed from carrier facing surface 203 to chip facing surface 202 of each interposer 200 via contacts 220 and internally formed wires.

Each interposer 200 may be connected upon particular contacts 420 of processing chip 400 such that at least the respective IC chips 100 upon the interposer 200 may be positioned within a topographic feature 30, upon when other contacts 420 of processing IC chip 400 are electrically connected to respective contacts 20 of carrier 10, as exemplarily depicted in FIG. 13.

The processing chip 400 may be electrically connected to interposer 200 of package 300 by connecting respective contacts 420 and respective contacts 220 on or in chip facing surface 202 of interposer 200 with respective processing-chip-interposer interconnects 510.

The power chip 810 may be electrically connected to interposer 200 by connecting respective contacts 820 and respective contacts 220 on or in chip facing surface 202 of interposer 200 with respective power processing-chip-interposer interconnects 850. Power processing-chip-interposer interconnects 850 may be solder, C4 solder, micro solder, buttons, posts, pins, or the like, that are electrically conductive to allow current to flow between a contact 820 and a contact 220. In some implementations, power processing-chip-interposer interconnect 850 is the same or similar size interconnect relative to processing-chip-interposer interconnect 510.

Underfill 302 may be also included within IC package 800 between the interposer 200 and IC processing chip 400 and/or between the interposer 200 and the power IC chip 400. Underfill 302 is electrically-insulating and may substantially surround interconnects 510, 850 may electrically isolate individual interconnects 510, 850 and may provide mechanical support between interposer 200 and processing IC chip 400 and power IC chip 800. Underfill 302 may also prevent damage to individual interconnects 510, 850 due to thermal expansion mismatches between interposer 200 and processing chip 400 and power IC chip 800.

FIG. 13 a cross section view of an exemplary IC package 900, in accordance with one or more embodiments of the present invention. IC package 900 includes package 800 and at least carrier 10. IC package 900 may further include underfill 630, thermal interface 640, cover 650, and/or seal band 660.

The IC package 800 may be electrically connected to carrier 10 by connecting respective carrier contacts 20 and respective contacts 420 of processing IC chip and by connecting respective carrier contacts 20 and respective contacts 820 of power IC chip 810 with respective carrier-IC chip interconnects 910. Carrier-interposer interconnect 910 may be solder, C4 solder, micro solder, buttons, posts, pins, or the like, that are electrically conductive to allow current to flow between a contact 420 or 820 and a contact 20. In some implementations, carrier-IC chip interconnect 910 is the same type of interconnect as processing-chip-interposer interconnect 510. In some implementations, carrier-IC chip interconnects 910 is a larger interconnect relative to interconnects 310, 510, 850.

IC package 800 may be positioned relative to carrier 10 such that at least each IC chip 100 is located within a respective topographic feature 30 of carrier 10, upon when contacts 420, 820 are electrically connected to respective contacts 20 of carrier 10 by carrier-IC chip interconnects 910. In other words, at least carrier surface 102 of IC chip 100 is between the chip facing surface 12 of carrier 10 and chip facing surface 32 of topographic feature 30. In other implementations, respective interposers 200 may also be positioned with a topographic feature 30. As such, the shape of topographic feature 30 may be dictated by the perimeter shapes of at least the IC chip 100 and/or interposer 200 for which topographic feature 30 provides clearance. For example, a one micron to fifty-millimeter clearance may be provided between chip facing surface 32, front surface 34, rear surface 35, side surface 36, and side surface 37 of the topographic feature 30 and an associated facing respective IC chip 100 surface(s), respective mold 304 surface(s), and/or respective interposer 200 surface(s).

Underfill 630 may be included within IC package 900 and is electrically-insulating, may substantially surround interconnects 910, may electrically isolate individual interconnects 910, and may provide mechanical support between package 800 and carrier 10. As such, underfill 630 may generally surround package 800 between contact surface 412 of processing chip 400 and surface 813 of power IC chip 810 and contact surface 12 of carrier 10. Underfill 630 may also prevent damage to individual interconnects 910 due to thermal expansion mismatches between carrier 10, interposer 200, processing chip 400, and/or power IC chip 810. For clarity, underfill 630 may exist within the clearance between the topographic feature 30 and the IC chip 100/mold 304/or the like and between the processing IC chip 400 and power IC chip 810 and carrier 10 surrounding interconnects 910.

Cover 650 may be attached to carrier 10 with seal band 660 to cover, encapsulate, or the like, processing chip 400 and power IC chip 810. Generally, during operation of processing chip 400 and power IC chip 810, heat needs to be removed therefrom. In this situation, cover 650 is both a cover and a conduit for heat transfer. As such, thermal interface material 640 may thermally connect the underside surface of cover 650 and the upper surface 413 of processing chip 400 and the upper surface 813 of power IC chip 810.

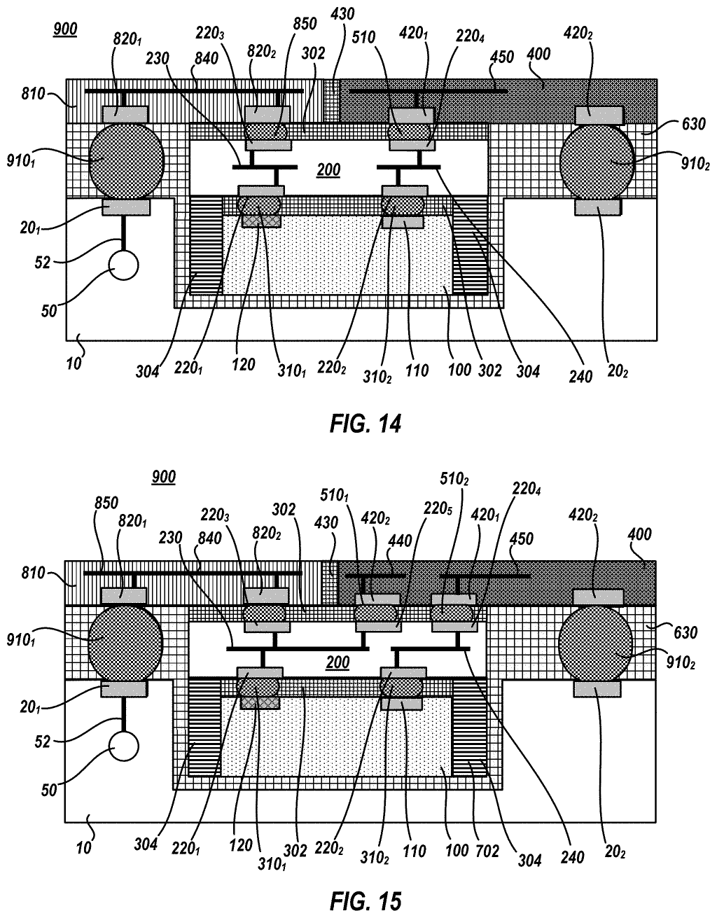

FIG. 14 depicts a detailed cross section view of IC package 900, in accordance with one or more embodiments of the present invention. IC chip 100 is electrically connected to interposer 200 by interconnect 310₁ which is connected to power contact 120 of IC chip 100 and contact 220₁ of interposer 200 and by interconnect 310₂ which is connected to I/O contact 110 of IC chip 100 and contact 220₂ of interposer 200.

Processing IC chip 400 is electrically connected to interposer 200 by interconnect 510 which is connected to contact 420₁ of processing IC chip 400 and contact 220₄ of interposer 200. Processing IC chip 400 is electrically connected to carrier 10 by interconnect 910₂ which is connected to contact 420₂ of processing IC chip 400 and contact 202 of carrier 10. Processing IC chip 400 may include an electrical path 450 which is electrically connected to contact 420₁.

Power IC chip 810 is electrically connected to interposer 200 by interconnect 850 which is connected to contact 820₂ of power IC chip 810 and contact 220₃ of interposer 200. Power IC chip 810 is electrically connected to carrier 10 by interconnect 910₁ which is connected to contact 820₁ of power IC chip 810 and contact 201 of carrier 10. Power IC chip 810 may include an electrical path 840 which is electrically connected to contact 820₁ and is electrically connected to contact 820₂.

Interposer 200 may include electrical path 230 and electrical path 240. Path 230, 240 may include various wiring line features as are known in the art. Path 230 may be electrically connected to contact 220₁ and to contact 220₃. Path 240 may be electrically connected to contact 220₂ and to contact 220₄.

To obtain data from the IC chip 100, IC processing chip 400 may send a obtain access instruction or signal by way of path 450 to contact 420₁. The obtain access instruction or signal passes through interposer 200 by path 240 and is received by IC chip 100 at I/O contact 110. In turn, IC chip 100 provides the applicable requested data cached or stored there within within IC chip 100 and provides such data to IC processing chip 400 by the same or different electrical path that which was used by IC chip 100 to receive the obtain access instruction. To pass data to the IC chip 100, IC processing chip 400 may send a pass access instruction or signal by way of path 450 to contact 420₁. The pass access instruction or signal passes through interposer 200 by path 240 and is received by IC chip 100 at I/O contact 110. In turn, IC chip 100 caches or stores the data included in the pass access instruction there within. Similarly, source/ground 50, which may be located in carrier 10, as shown in in power IC chip 810, may provide electrical potential or ground, respectively, to a respective power/ground contact 120 IC chip 100 by way of path 840, 230.

FIG. 15 depicts a detailed cross section view of IC package 900, in accordance with one or more embodiments of the present invention wherein the processing IC chip 400, in addition to IC chip 100, receives power/ground potential and/or current from power IC chip 400 by way of path 230 of interposer 200.

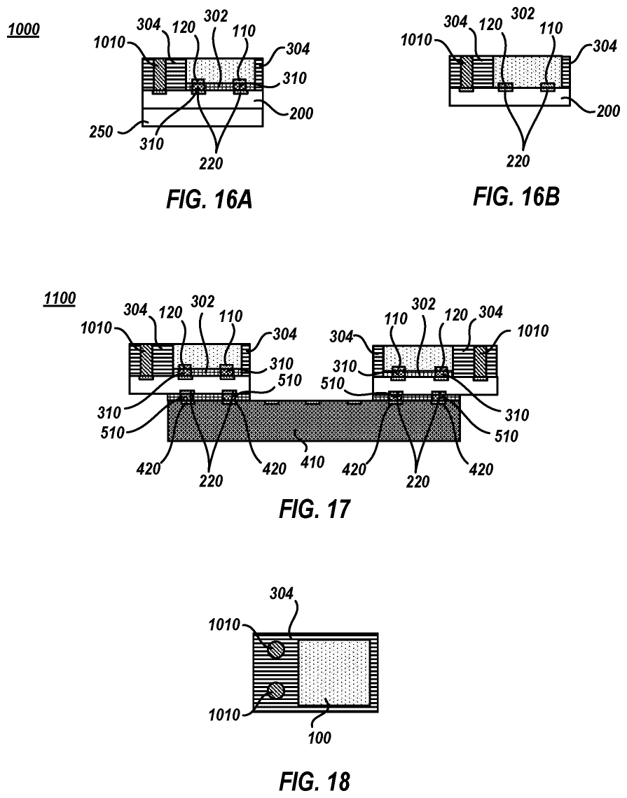

FIG. 16A and FIG. 16B depict a cross section view of an exemplary IC package 1000 fabrication stage, in accordance with one or more embodiments of the present invention. FIG. 16A depicts an implementation wherein IC chip 100 is connected to interposer 200 by interconnects 310 and FIG. 16B depicts an implementation wherein interposer 200 is formed upon IC chip 100 is. IC package 1000 includes handle 250, interposer 200, and IC chip 100.

In the present fabrication stage, interposer 200 is formed upon handle 250. Subsequently, IC chip 100 may be connected to interposer 200 as shown in FIG. 16A, or interposer 200 may be formed upon IC chip 100, as shown in FIG. 16B.

As shown in FIG. 16A, each IC chip 100 may be electrically connected to an interposer 200 by connecting a power contact 120 and a first interposer contact 220 upon surface 203 with a first IC-chip-interposer interconnect 310, by connecting a ground contact 120 and a second interposer contact 220 upon surface 203 with a second IC-chip-interposer interconnect 310, and/or by connecting a I/O contact 110 and a third interposer contact 220 upon surface 203 with a third IC-chip-interposer interconnect 310. As shown in FIG. 16B, each IC chip 100 may be electrically connected to an interposer 200 by directly connecting a power contact 120 and a first interposer contact 220 upon surface 203, by directly connecting a ground contact 120 and a second interposer contact 220 upon surface 203, and/or by directly connecting a I/O contact 110 and a third interposer contact 220 upon surface 203.

IC package 1000 may further include underfill 302 between the IC chip 100 and interposer 200. Underfill 302 is electrically-insulating and may substantially surround interconnects 310, may electrically isolate individual interconnects 310, and may provide mechanical support between package IC chip 100 and interposer 200. Underfill 302 may also prevent damage to individual interconnects 310 due to thermal expansion mismatches between interposer 200 and IC chip 100.

IC package 1000 may further include mold 304 material formed around the circumference of IC chip 100 and upon interposer 200. The side surfaces of mold 304 may be coplanar with the side surface of interposer 200. The front and rear surfaces of mold 304 may be coplanar with respective front and rear surfaces of interposer 200.

IC package 1000 may further include one or more conductive pillars 1010, such as a via, post, column, or the like that extends through mold 304 and contacts an interposer contact 220 upon surface 203.

FIG. 17 depicts a cross section view of an exemplary IC package 1100 fabrication stage, in accordance with one or more embodiments of the present invention. IC package 1100 includes interposers 200, IC chips 100, and processing IC chip 400.

IC package 1100 may be formed by removing handle 250 from each interposer 200. Contacts 220 may be formed upon carrier facing surface 203 of each interposer 200. Such contacts 220 may connected to one or more wires located within the respective interposer 200. As such, electrical pathways may be formed from carrier facing surface 203 to chip facing surface 202 of each interposer 200 via contacts 220 and internally formed wires.

The processing chip 400 may be electrically connected to interposer 200 of package 300 by connecting respective contacts 420 and respective contacts 220 on or in chip facing surface 202 of interposer 200 with respective processing-chip-interposer interconnects 510. Processing-chip-interposer interconnect 510 may be solder, C4 solder, micro solder, buttons, posts, pins, or the like, that are electrically conductive to allow current to flow between a contact 420 and a contact 220. In some implementations, processing-chip-interposer interconnect 510 is a larger interconnect relative to IC-chip-interposer interconnect 310. For example, a diameter of the IC-chip-interposer interconnect 310 may be on the micrometer bump scale (e.g., 50 micrometers, etc.) while a diameter of the processing-chip-interposer interconnect 510 may be a larger C4 bump scale (e.g., 150 micrometers, etc.).

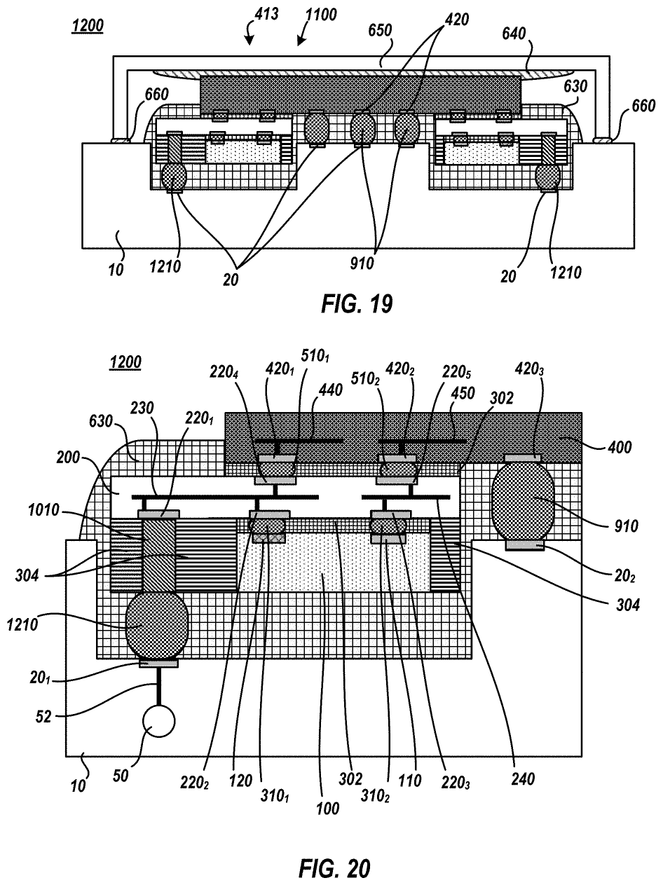

Each interposer 200 may be connected upon particular contacts 420 of processing chip 400 such that at least the respective IC chips 100 upon the interposer 200 may be positioned within a topographic feature 30, upon when other contacts 420 of processing IC chip 400 are electrically connected to respective contacts 20 of carrier 10, as exemplarily depicted in FIG. 19.

Underfill 302 may be included within IC package 1100 between the interposer 200 and processing IC chip 400. Underfill 302 is electrically-insulating and may substantially surround interconnects 510, may electrically isolate individual interconnects 510, and may provide mechanical support between processing chip 400 and interposer 200. Underfill 302 may also prevent damage to individual interconnects 510 due to thermal expansion mismatches between interposer 200 and processing chip 400.

FIG. 18 depicts a view of an exemplary IC chip 100 surrounded by mold 304 with conductive posts 1010 formed therewith, in accordance with one or more embodiments of the present invention. Posts 1010 may be formed upon contact 220 prior to the formation of mold 304 material around IC chip 100. Alternatively, mold 304 material may be formed around the circumference of IC chip 100. Subsequently a post trenches may be formed within the mold 304 material thereby exposing a respective contact 220 of interposer 200. Posts 1010 may be then be formed within each post trench.

FIG. 19 depicts a cross section view of an exemplary IC package 1200 fabrication stage, in accordance with one or more embodiments of the present invention. IC package 1200 includes package 1100 and carrier 10. IC package 1200 may further include underfill 630, thermal interface 640, cover 650, and/or seal band 660.

The IC package 1100 may be electrically connected to carrier 10 by connecting respective carrier contacts 20 and respective contacts 420 of processing IC chip 400 with respective carrier-IC chip interconnects 910 and by connecting respective carrier contacts 20 and respective pillars 1010 of package 1000 with a carrier-pillar interconnect 1210. Carrier-pillar interconnect 1210 may be solder, C4 solder, micro solder, buttons, posts, pins, or the like, that are electrically conductive to allow current to flow between a pillar 1010 and a contact 20. Carrier-Pillar interconnect 1210 may be formed at wafer level upon pillar 1010. In some implementations, carrier-pillar interconnect 1210 is the same type of interconnect as processing-chip-interposer interconnect 510. In some implementations, carrier-pillar interconnect 1210 is the same type of interconnect as carrier-IC chip interconnect 910.

IC package 1200 may be positioned relative to carrier 10 such that each IC chip 100 and associated mold 304 material is located within a respective topographic feature 30 of carrier 10, upon when contacts 420 are electrically connected to respective contacts 20 of carrier 10 by carrier-IC chip interconnects 910. In other words, at least carrier surface 102 of IC chip 100 is between the chip facing surface 12 of carrier 10 and chip facing surface 32 of topographic feature 30 and mold 304 material is between the left surface and right surface of the topographic feature 30. As such, the shape of topographic feature 30 may be dictated by the perimeter shapes of the IC chip 100 and mold 304 material, combination, for which it provides clearance.

Underfill 630 may be included within IC package 1200 and is electrically-insulating, may substantially surround interconnects 910 and 1210, may electrically isolate individual interconnects 910 and 1210, and may provide mechanical support between package 1100 and carrier 10. As such, underfill 630 may generally surround package 1100 between contact surface 412 of processing chip 400 and contact surface 12 of carrier 10. Underfill 630 may also prevent damage to individual interconnects 910 and 1210, due to thermal expansion mismatches between carrier 10, interposer 200, and processing chip 400. For clarity, underfill 630 may exists within the clearance between mold 304 material and the associated topographic feature 30 of carrier 10, between the processing IC chip 400 and carrier 10 surrounding interconnects 910, and between the IC chip 100 and carrier 10 surrounding interconnects 1210.

Cover 650 may be attached to carrier 10 with seal band 660 to cover, encapsulate, or the like, processing chip 400. Generally, during operation of processing chip 400, heat needs to be removed therefrom. In this situation, cover 650 is both a cover and a conduit for heat transfer. As such, thermal interface material 640 may thermally connect the underside surface of cover 650 and the upper surface 413 of processing chip 400.

FIG. 20 depicts a detailed cross section view of IC package 1200, in accordance with one or more embodiments of the present invention. IC chip 100 is electrically connected to interposer 200 by interconnect 310₁ which is connected to power contact 120 of IC chip 100 and contact 220₂ of interposer 200 and by interconnect 310₂ which is connected to I/O contact 110 of IC chip 100 and contact 220₃ of interposer 200.

Processing IC chip 400 is electrically connected to interposer 200 by interconnect 510₁ which is connected to contact 420₁ of processing IC chip 400 and contact 220₄ of interposer 200 and is electrically connected to interposer 200 by interconnect 510₂ which is connected to contact 420₂ of processing IC chip 400 and contact 220₅ of interposer 200. Processing IC chip 400 is electrically connected to carrier 10 by interconnect 910 which is connected to contact 420₃ of processing IC chip 400 and contact 202 of carrier 10. Processing IC chip 400 may include an electrical path 440 which is electrically connected to contact 420₁ and may include an electrical path 450 which is electrically connected to contact 420₂. Path 440, 450 may include various wiring line features as are known in the art.

Package 1000 is electrically connected to carrier 10 by interconnect 1210 which is connected to contact 20₁ of carrier 10 and to pillar 1010. Interposer 200 may include electrical path 230 and electrical path 240. Path 230, 240 may include various wiring line features as are known in the art. Path 230 may be electrically connected to contact 220₁ and to contact 220₂. Path 240 may be electrically connected to contact 220₃.

To obtain data from the IC chip 100, IC processing chip 400 may send a obtain access instruction or signal by way of path 450 to contact 420₂. The obtain access instruction or signal passes through interposer 200 by path 240 and is received by IC chip 100 at contact 110. In turn, IC chip 100 provides the applicable requested data cached or stored there within and provides such data to IC processing chip 400 by the same or different electrical path that which was used by IC chip 100 to receive the obtain access instruction. To pass data to the IC chip 100, IC processing chip 400 may send a pass access instruction or signal by way of path 450 to contact 420₂. The pass access instruction or signal passes through interposer 200 by path 240 and is received by IC chip 100 at contact 110. In turn, IC chip 100 caches or stores the data included in the pass access instruction there within. Similarly, source/ground 50, which may be located in carrier 10 as shown, or in a system or mother board that which is electrically connected to carrier 10, may provide electrical potential or ground, respectively, to IC chip 100 and/or to processing IC chip 400 by way of path 230 to power contact 120.

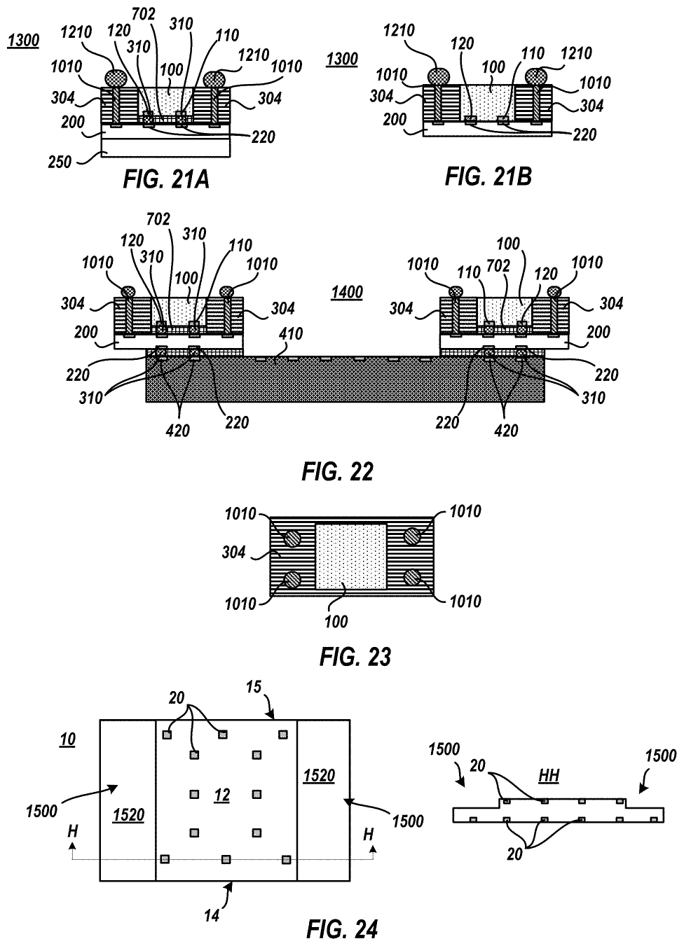

FIG. 21A and FIG. 21B depict a cross section view of an exemplary IC package 1300 fabrication stage, in accordance with one or more embodiments of the present invention. FIG. 21A depicts an implementation wherein IC chip 100 is connected to interposer 200 by interconnects 310 and FIG. 21B depicts and implementation wherein interposer 200 is formed upon IC chip 100. IC package 1300 includes handle 250, interposer 200, and IC chip 100.

In the present fabrication stage, interposer 200 may be formed upon a handle 250. Subsequently, IC chip 100 may be connected to interposer 200 as shown in FIG. 21A, or interposer 200 may be formed upon IC chip 100, as shown in FIG. 21B.

As shown in FIG. 21A, each IC chip 100 may be electrically connected to an interposer 200 by connecting a power contact 120 and a first interposer contact 220 upon surface 203 with a first IC-chip-interposer interconnect 310, by connecting a ground contact 120 and a second interposer contact 220 upon surface 203 with a second IC-chip-interposer interconnect 310, and/or by connecting a I/O contact 110 and a third interposer contact 220 upon surface 203 with a third IC-chip-interposer interconnect 310. As shown in FIG. 21B, each IC chip 100 may be electrically connected to an interposer 200 by directly connecting a power contact 120 and a first interposer contact 220 upon surface 203, by directly connecting a ground contact 120 and a second interposer contact 220 upon surface 203, and/or by directly connecting a I/O contact 110 and a third interposer contact 220 upon surface 203.

IC package 1300 may further include underfill 302 between IC chip 100 and interposer 200. Underfill 302 is electrically-insulating and may substantially surround interconnects 310, may electrically isolate individual interconnects 310, and may provide mechanical support between package IC chip 100 and interposer 200. Underfill 302 may also prevent damage to individual interconnects 310 due to thermal expansion mismatches between interposer 200 and IC chip 100. For clarity, underfill 302 may exist between the IC chip 100 and interposer 200 surrounding interconnects 310.

IC package 1300 may further include mold 304 material formed around the circumference of IC chip 100 and upon interposer 200. The side surfaces of mold 304 may be coplanar with the side surface of interposer 200. The front and rear surfaces of mold 304 may be coplanar with respective front and rear surfaces of interposer 200.

IC package 1000 may further include conductive one or more pillars 1010, such as a via, post, column, or the like that extends through mold 304 and contacts a respective interposer contact 220 upon surface 203.

FIG. 22 depicts a cross section view of an exemplary IC package 1400 fabrication stage, in accordance with one or more embodiments of the present invention. IC package 1400 includes interposers 200, IC chips 100, and processing IC chip 400.

IC package 1400 may be formed by removing handle 250 from each interposer 200. Contacts 220 may be formed upon carrier facing surface 203 of each interposer 200. Such contacts 220 may connected to one or more wires located within the respective interposer 200. As such, electrical pathways may be formed from carrier facing surface 203 to chip facing surface 202 of each interposer 200 via contacts 220 and internally formed wires.

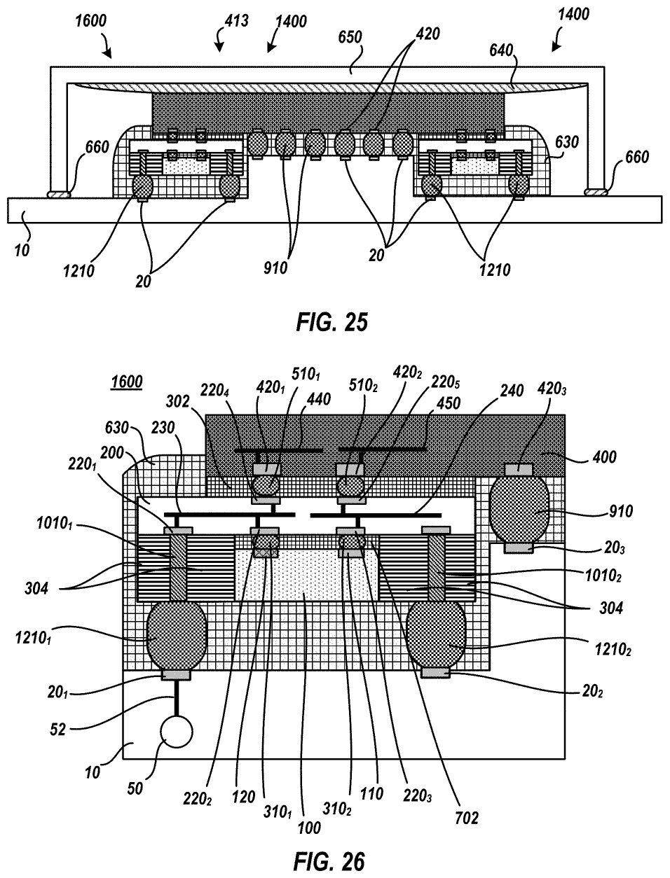

The processing chip 400 may be electrically connected to interposer 200 of package 300 by connecting respective contacts 420 and respective contacts 220 on or in chip facing surface 202 of interposer 200 with respective processing-chip-interposer interconnects 510. Each interposer 200 may be connected upon particular contacts 420 of processing chip 400 such that at least the respective IC chips 100 upon the interposer 200 may be positioned within a topographic feature 1520, shown in FIG. 24, upon when other contacts 420 of processing IC chip 400 are electrically connected to respective contacts 20 of carrier 10, as exemplarily depicted in FIG. 25.

Underfill 302 may be included within IC package 1400 between interposer 200 and processing IC chip 400. Underfill 302 is electrically-insulating and may substantially surround interconnects 510, may electrically isolate individual interconnects 510, and may provide mechanical support between package processing IC chip 400 and interposer 200. Underfill 302 may also prevent damage to individual interconnects 510 due to thermal expansion mismatches between interposer 200 and processing chip 400.

FIG. 23 depicts a view of an exemplary IC chip 100 surrounded by mold 304 with conductive posts 1010 formed therewith, in accordance with one or more embodiments of the present invention. Posts 1010 may be formed upon contact 220 prior to the formation of mold 304 material around IC chip 100. Alternatively, mold 304 material may be formed around the circumference of IC chip 100. Subsequently a post trenches may be formed within the mold 304 material thereby exposing a respective contact 220 of interposer 200. Posts 1010 may be then formed within each post trench.

FIG. 24 depicts views of an exemplary IC package carrier 10, in accordance with one or more embodiments of the present invention. Carrier 10 includes one or more topographic features 1500 that provide clearance for a respective IC chip. As depicted, topographic feature 1500 extends internally into carrier 10 and may be a recess, void, cutout, or the like, that extends from the front surface 14 to the rear surface 15 of carrier 10. Topographic feature 1500 includes a chip facing surface 1520 that is recessed internally from chip facing surface 12. One or more carrier contacts 20 may be included upon or within chip facing surface 1520 of topographic feature 1500.

FIG. 25 depicts a cross section view of an exemplary IC package 1600, in accordance with one or more embodiments of the present invention. IC package 1600 includes package 1400 and at least carrier 10. IC package 1600 may further include underfill 630, thermal interface 640, cover 650, and/or seal band 660.

The IC package 1600 may be electrically connected to carrier 10 by connecting respective carrier contacts 20 and respective contacts 420 of processing IC chip 400 with respective carrier-IC chip interconnects 910 and by connecting respective carrier contacts 20 and respective pillars 1010 of package 1300 with a carrier-pillar interconnect 1210.

IC package 1600 may be positioned relative to carrier 10 such that each IC chip 100 and mold 304 material are located within a respective topographic feature 1500 of carrier 10, upon when contacts 420 are electrically connected to respective contacts 20 of carrier 10 by carrier-IC chip interconnects 910. In other words, at least carrier surface 102 of IC chip 100 is between the chip facing surface 12 of carrier 10 and chip facing surface 1520 of topographic feature 1500. As such, the shape of topographic feature 1500 may be dictated by the perimeter shapes of the IC chip 100 and mold 304 material for which it provides clearance.

Underfill 630 may be included within IC package 1600 and is electrically-insulating, may substantially surround interconnects 910 and 1210, may electrically isolate individual interconnects 910 and 1210, and may provide mechanical support between package 1400 and carrier 10. As such, underfill 630 may generally surround package 1400 between contact surface 412 of processing chip 400 and contact surface 12 of carrier 10. Underfill 630 may also prevent damage to individual interconnects 910 and 1210, due to thermal expansion mismatches between carrier 10, interposer 200, and processing chip 400. For clarity, underfill 630 may exist within the clearance between IC chip 100 and mold 304 material and the associated topographic feature 1500 of carrier 10 surrounding interconnects 1210 and between the processing IC chip 400 and carrier 10 surrounding interconnects 910. In some embodiments, under fill 630 may include a different material between carrier 10 and structure 1300 may electrically isolate individual interconnects 1210 and may provide mechanical support between package 1300 and carrier 10.

Cover 650 may be attached to carrier 10 with seal band 660 to cover, encapsulate, or the like, processing chip 400. Generally, during operation of processing chip 400, heat needs to be removed therefrom. In this situation, cover 650 is both a cover and a conduit for heat transfer. As such, thermal interface material 640 may thermally connect the underside surface of cover 650 and the upper surface 413 of processing chip 400.

FIG. 26 depicts a detailed cross section view of IC package 1600, in accordance with one or more embodiments of the present invention. IC chip 100 is electrically connected to interposer 200 by interconnect 310₁ which is connected to power contact 120 of IC chip 100 and contact 220₂ of interposer 200 and by interconnect 310₂ which is connected to I/O contact 110 of IC chip 100 and contact 220₃ of interposer 200.

Processing IC chip 400 is electrically connected to interposer 200 by interconnect 510₁ which is connected to contact 420₁ of processing IC chip 400 and contact 220₄ of interposer 200 and is electrically connected to interposer 200 by interconnect 510₂ which is connected to contact 420₂ of processing IC chip 400 and contact 220₅ of interposer 200. Processing IC chip 400 is electrically connected to carrier 10 by interconnect 910 which is connected to contact 420₃ of processing IC chip 400 and contact 20₃ of carrier 10. Processing IC chip 400 may include an electrical path 440 which is electrically connected to contact 420₁ and may include an electrical path 450 which is electrically connected to contact 420₂. Path 440, 450 may include various wiring line features as are known in the art.

Package 1400 is further electrically connected to carrier 10 by interconnect 1210₁ which is connected to contact 201 of carrier 10 and to pillar 1010₁and by interconnect 1210₂ which is connected to contact 20₂ of carrier 10 and to pillar 1010₂. Interposer 200 may include electrical path 230 and electrical path 240. Path 230, 240 may include various wiring line features as are known in the art. Path 230 may be electrically connected to contact 220₁ and to contact 220₂. Path 240 may be electrically connected to contact 220₃.

To obtain data from the IC chip 100, IC processing chip 400 may send a obtain access instruction or signal by way of path 450 to contact 420₂. The obtain access instruction or signal passes through interposer 200 by path 240 and is received by IC chip 100 at I/O contact 110. In turn, IC chip 100 provides the applicable requested data and provides such data to IC processing chip 400 by the same or different electrical path that which was used by IC chip 100 to receive the obtain access instruction. To pass data to the IC chip 100, IC processing chip 400 may send a pass access instruction or signal by way of path 450 to contact 420₂. The pass access instruction or signal passes through interposer 200 by path 240 and is received by IC chip 100 at contact 110. In turn, IC chip 100 receives and mays cache, or otherwise store data included in the pass access instruction. Similarly, source/ground 50, which may be located in carrier 10 as shown, or in a system or mother board that which is electrically connected to carrier 10, may provide electrical potential or ground, respectively, to IC chip 100 and/or to processing IC chip 400 by way of path 230.

In the depicted embodiment, interconnect 1210₂ may serve primarily a mechanical purpose of supporting package 1300 as pillar 1010₂ may not be electrically connected to any electrical pathway within interposer 200.

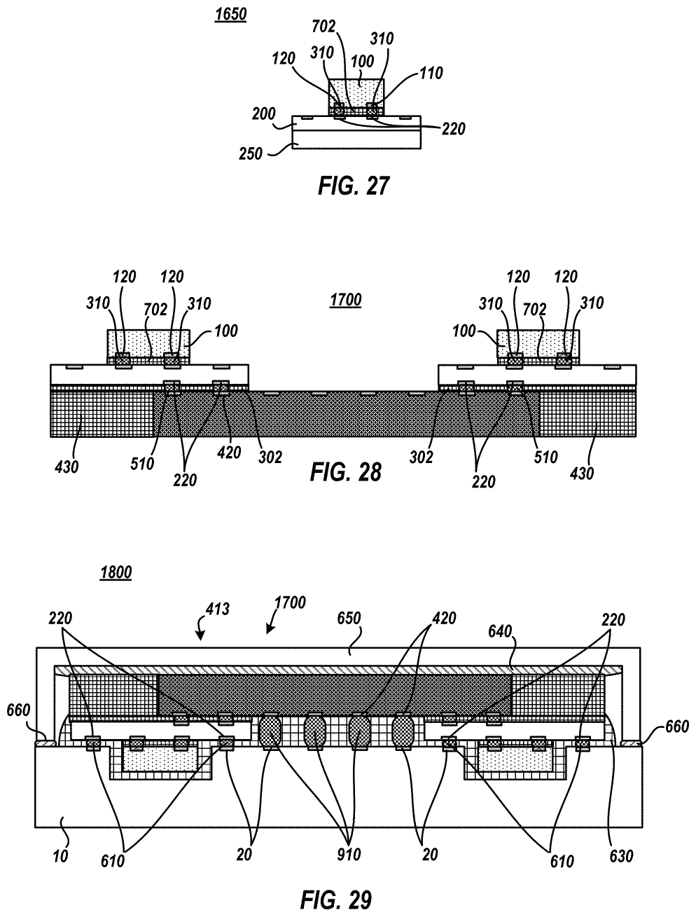

FIG. 27 depicts a cross section view of an exemplary IC package 1650 fabrication stage, in accordance with one or more embodiments of the present invention. In the present fabrication stage, interposer 200 is formed upon a handle 250. Subsequently, IC chip 100 may be connected to interposer 200. Each IC chip 100 may be electrically connected to an interposer 200 by connecting a power contact 120 and a first interposer contact 220 upon surface 203 with a first IC-chip-interposer interconnect 310, by connecting a ground contact 120 and a second interposer contact 220 upon surface 203 with a second IC-chip-interposer interconnect 310, and/or by connecting a I/O contact 110 and a third interposer contact 220 upon surface 203 with a third IC-chip-interposer interconnect 310.

IC package 1650 may further include underfill 302 between IC chip 100 and interposer 200. Underfill 302 is electrically-insulating and may substantially surround interconnects 310, may electrically isolate individual interconnects 310, and may provide mechanical support between package IC chip 100 and interposer 200. Underfill 302 may also prevent damage to individual interconnects 310 due to thermal expansion mismatches between interposer 200 and IC chip 100.

FIG. 28 depicts a cross section view of an exemplary IC package 1700 fabrication stage, in accordance with one or more embodiments of the present invention. IC package 1700 includes IC processing chip 400, carriers 200, and IC chips 100. IC package 1700 may be formed by removing handle 250 from each interposer 200. Contacts 220 may be formed upon carrier facing surface 203 of each interposer 200. Such contacts 220 may connected to one or more wires located within the respective interposer 200. As such, electrical pathways may be formed from carrier facing surface 203 to chip facing surface 202 of each interposer 200 via contacts 220 and internally formed wires.

The processing chip 400 may be electrically connected to interposer 200 of package 300 by connecting respective contacts 420 and respective contacts 220 on or in chip facing surface 202 of interposer 200 with respective processing-chip-interposer interconnects 510. Each interposer 200 may be connected upon particular contacts 420 of processing chip 400 such that at least the respective IC chips 100 upon the interposer 200 may be positioned within a topographic feature 30, upon when other contacts 420 of processing IC chip 400 are electrically connected to respective contacts 20 of carrier 10, as exemplarily depicted in FIG. 29.

In some embodiments, a filler 430 may be connected to chip 400 in package 1700. Filler 430 generally fills space within the IC package and may be for example, mold material, or the like. Filler 430 may have a carrier facing surface 432, a top surface 433, front surface 434, rear surface 435, side surface 436, and side surface 437. Top surface 433 of filler 430 may be coplanar with top surface 413 of chip 400, and the like.

Underfill 302 may be included within IC package 1700 between interposer 200 and processing chip 400 and/or between interposer 200 and filler 430. Underfill 302 is electrically-insulating and may substantially surround interconnects 510, may electrically isolate individual interconnects 510, and may provide mechanical support between interposer 200 and filler 430 and between interposer 200 and IC processing chip 400. Underfill 302 may also prevent damage to individual interconnects 510 due to thermal expansion mismatches between interposer 200 and processing chip 400.

FIG. 29 depicts a cross section view of an exemplary IC package 1800, in accordance with one or more embodiments of the present invention. IC package 1800 includes package 1700 and at least carrier 10. IC package 1800 may further include underfill 630, thermal interface 640, cover 650, and/or seal band 660.

The IC package 1700 may be electrically connected to carrier 10 by connecting respective carrier contacts 20 and respective contacts 420 of processing IC chip 400 with respective carrier-IC chip interconnects 910 and by connecting respective carrier contacts 20 and respective contacts 220 of interposer 200 with a carrier-interposer interconnects 610. IC package 1700 may be positioned relative to carrier 10 such that each IC chip 100 is located within a respective topographic feature 30 of carrier 10, upon when the IC package 1700 is electrically connected to carrier 10. In other words, at least carrier facing surface 102 of IC chip 100 is between the chip facing surface 12 of carrier 10 and chip facing surface 32 of topographic feature 30. As such, the shape of topographic feature 30 may be dictated by the perimeter shape of the IC chip 100 for which it provides clearance.

Underfill 630 may be included within IC package 1800 and is electrically-insulating, may substantially surround interconnects 610 and 910, may electrically isolate individual interconnects 610 and 910, and may provide mechanical support between package 1700 and carrier 10. As such, underfill 630 may generally surround package 1700 between contact surface 412 of processing chip 400 and contact surface 12 of carrier 10. Underfill 630 may also prevent damage to individual interconnects 610 and 910, due to thermal expansion mismatches between carrier 10, interposer 200, and processing chip 400. For clarity, underfill 630 may exist surrounding package 1700, within the clearance between package IC chip 100 and the associated topographic feature 30 of carrier 10, between the processing IC chip 400 and carrier 10 surrounding interconnects 910, and between interposer 200 and carrier 10 surrounding interconnects 610.

Cover 650 may be attached to carrier 10 with seal band 660 to cover, encapsulate, or the like, processing chip 400. Generally, during operation of processing chip 400, heat needs to be removed therefrom. In this situation, cover 650 is both a cover and a conduit for heat transfer. As such, thermal interface material 640 may thermally connect the underside surface of cover 650 and the upper surface 413 of processing chip 400.

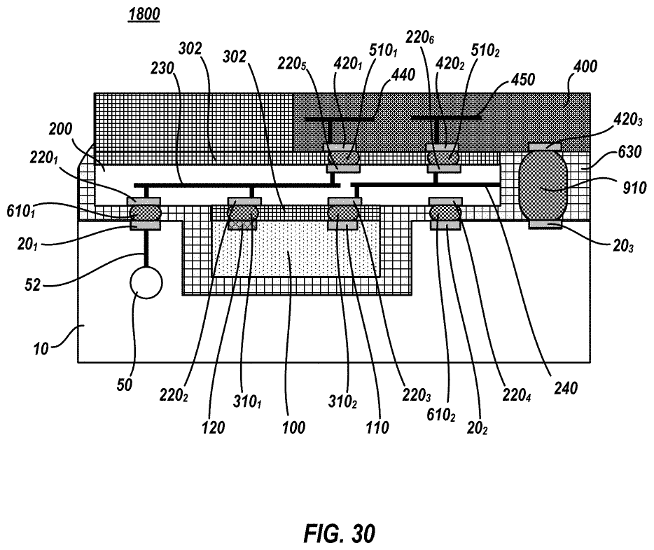

FIG. 30 depicts a detailed cross section view of IC package 1800, in accordance with one or more embodiments of the present invention. IC chip 100 is electrically connected to interposer 200 by interconnect 310₁ which is connected to power contact 120 of IC chip 100 and contact 220₂ of interposer 200 and by interconnect 310₂ which is connected to I/O contact 110 of IC chip 100 and contact 220₃ of interposer 200.

Processing IC chip 400 is electrically connected to interposer 200 by interconnect 510₁ which is connected to contact 420₁ of processing IC chip 400 and contact 220₅ of interposer 200 and is electrically connected to interposer 200 by interconnect 510₂ which is connected to contact 420₂ of processing IC chip 400 and contact 2206 of interposer 200. Processing IC chip 400 is electrically connected to carrier 10 by interconnect 910 which is connected to contact 420₃ of processing IC chip 400 and contact 20₃ of carrier 10. Processing IC chip 400 may include an electrical path 440 which is electrically connected to contact 420₁ and may include an electrical path 450 which is electrically connected to contact 420₂. Path 440, 450 may include various wiring line features as are known in the art.

Interposer 200 is electrically connected to carrier 10 by interconnect 6101 which is connected to contact 201 of carrier 10 and contact 220₁ of interposer 200 and by interconnect 6102 which is connected to contact 202 of carrier 10 and contact 220₄ of interposer 200. Interposer 200 may include electrical path 230 and electrical path 240. Path 230, 240 may include various wiring line features as are known in the art. Path 230 may be electrically connected to contact 220₁ and to contact 220₂. Path 240 may be electrically connected to contact 220₃.

To obtain data from the IC chip 100, IC processing chip 400 may send an obtain access instruction or signal by way of path 450 to contact 420₂. The obtain access instruction or signal passes through interposer 200 by path 240 and is received by IC chip 100 at contact 110. In turn, IC chip 100 provides the applicable requested data cached or stored there within and provides such data to IC processing chip 400 by the same or different electrical path that which was used by IC chip 100 to receive the obtain access instruction. To pass data to the IC chip 100, IC processing chip 400 may send a pass access instruction or signal by way of path 450 to contact 420₂. The pass access instruction or signal passes through interposer 200 by path 240 and is received by IC chip 100 at contact 110. In turn, IC chip 100 caches or stores the data included in the pass access instruction there within. Similarly, source/ground 50, which may be located in carrier 10 as shown, or in a system or mother board that which is electrically connected to carrier 10, may provide electrical potential or ground, respectively, to IC chip 100 and/or to processing IC chip 400 by way of path 230.

In the depicted embodiment, interconnect 610₂ may serve primarily a mechanical purpose of supporting package 1300 as contact 220₄ may not be electrically connected to any electrical pathway within interposer 200.

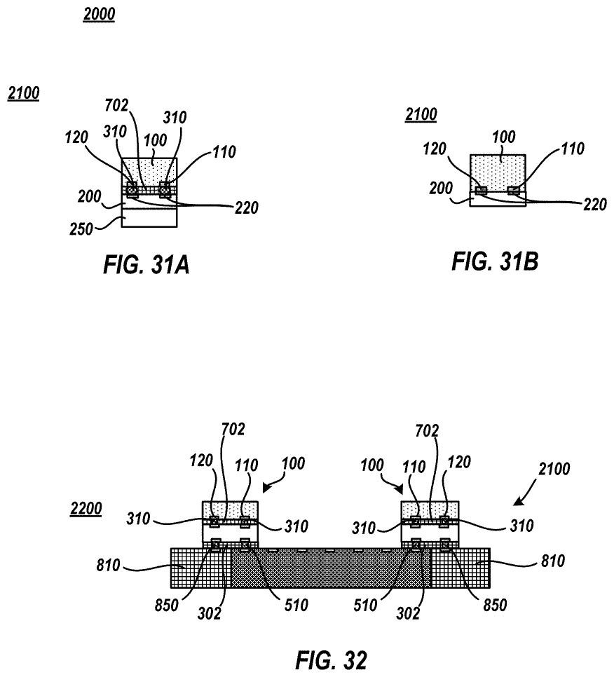

FIG. 31A and FIG. 31B depict a cross section view of an exemplary IC package 2100 fabrication stage, in accordance with one or more embodiments of the present invention. FIG. 31A depicts an implementation wherein IC chip 100 is connected to interposer 200 by interconnects 310 and FIG. 31B depicts and imputation wherein interposer 200 is formed upon IC chip 100. IC package 2100 includes handles 250, interposer 200, and IC chip 100.

In the present fabrication stage, interposer 200 is formed upon a handle 250. Subsequently, IC chip 100 may be connected to interposer 200 as shown in FIG. 31A, or interposer 200 may be formed upon IC chip 100, as shown in FIG. 31B.

As shown in FIG. 31A, each IC chip 100 may be electrically connected to an interposer 200 by connecting a power contact 120 and a first interposer contact 220 upon surface 203 with a first IC-chip-interposer interconnect 310, by connecting a ground contact 120 and a second interposer contact 220 upon surface 203 with a second IC-chip-interposer interconnect 310, and/or by connecting a I/O contact 110 and a third interposer contact 220 upon surface 203 with a third IC-chip-interposer interconnect 310. As shown in FIG. 31B, each IC chip 100 may be electrically connected to an interposer 200 by directly connecting a power contact 120 and a first interposer contact 220 upon surface 203, by directly connecting a ground contact 120 and a second interposer contact 220 upon surface 203, and/or by directly connecting a I/O contact 110 and a third interposer contact 220 upon surface 203.

IC package 2100 may further include underfill 302 between IC chip 100 and interposer 200. Underfill 302 is electrically-insulating and may substantially surround interconnects 310, may electrically isolate individual interconnects 310, and may provide mechanical support between package IC chip 100 and interposer 200. Underfill 302 may also prevent damage to individual interconnects 310 due to thermal expansion mismatches between interposer 200 and IC chip 100.

FIG. 32 depicts a cross section view of an exemplary IC package 2200 fabrication stage, in accordance with one or more embodiments of the present invention. IC package 2200 includes IC chips 100, interposers 200, and processing IC chip 400. IC package 2200 may be formed by removing handle 250 from each interposer 200. Contacts 220 may be formed upon carrier facing surface 203 of each interposer 200. Such contacts 220 may connected to one or more wires located within the respective interposer 200. As such, electrical pathways may be formed from carrier facing surface 203 to chip facing surface 202 of each interposer 200 via contacts 220 and internally formed wires.

The processing chip 400 may be electrically connected to interposer 200 of package 300 by connecting respective contacts 420 and respective contacts 220 on or in chip facing surface 202 of interposer 200 with respective processing-chip-interposer interconnects 510. Processing-chip-interposer interconnect 510 may be solder, C4 solder, micro solder, buttons, posts, pins, or the like, that are electrically conductive to allow current to flow between a contact 420 and a contact 220. In some implementations, processing-chip-interposer interconnect 510 is a larger interconnect relative to IC-chip-interposer interconnect 310. For example, a diameter of the IC-chip-interposer interconnect 310 may be on the micrometer bump scale (e.g., 50 micrometers, etc.) while a diameter of the processing-chip-interposer interconnect 510 may be a larger C4 bump scale (e.g., 150 micrometers, etc.).

Each interposer 200 may be connected upon particular contacts 420 of processing chip 400 such that at least the respective IC chips 100 upon the interposer 200 may be positioned within a topographic feature 30, upon when other contacts 420 of processing IC chip 400 are electrically connected to respective contacts 20 of carrier 10, as exemplarily depicted in FIG. 19.

Underfill 302 may be included within IC package 1100 between the interposer 200 and processing IC chip 400. Underfill 302 is electrically-insulating and may substantially surround interconnects 510, may electrically isolate individual interconnects 510, and may provide mechanical support between processing chip 400 and interposer 200. Underfill 302 may also prevent damage to individual interconnects 510 due to thermal expansion mismatches between interposer 200 and processing chip 400.

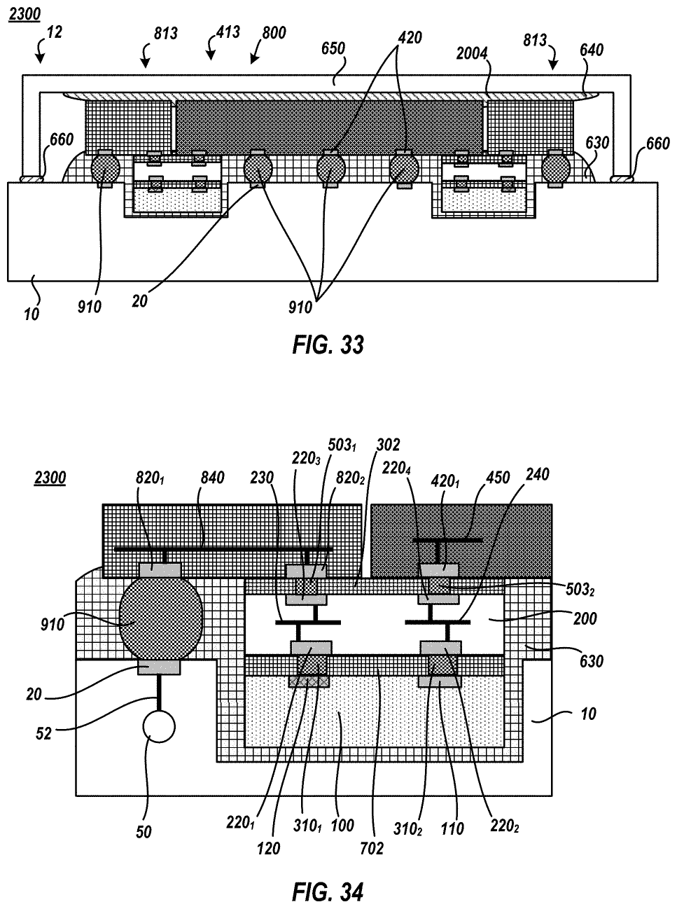

FIG. 33 depicts a cross section view of an exemplary IC package 2300, in accordance with one or more embodiments of the present invention. IC package 2300 includes package 2200 (having the fixture 2002 removed therefrom) and at least carrier 10. IC package 2300 may further include underfill 630, thermal interface 640, cover 650, and/or seal band 660.

The IC package 2300 may be electrically connected to carrier 10 by connecting respective carrier contacts 20 and respective contacts 420 of processing IC chip 400 with respective carrier-IC chip interconnects 910 and respective carrier contacts 20 and respective contacts 820 of power IC chip 810 with respective carrier-IC chip interconnects 910.

IC package 2300 may be positioned relative to carrier 10 such that each IC chip 100 is located within a respective topographic feature 30 of carrier 10, upon when the IC package 2300 is electrically connected to carrier 10. In other words, at least carrier facing surface 102 of IC chip 100 is between the chip facing surface 12 of carrier 10 and chip facing surface 32 of topographic feature 30. As such, the shape of topographic feature 30 may be dictated by the perimeter shape of the IC chip 100 for which it provides clearance.

Underfill 630 may be included within IC package 2300 and is electrically-insulating, may substantially surround interconnects 610 and 910, may electrically isolate individual interconnects 610 and 910, and may provide mechanical support between package 2200 and carrier 10. As such, underfill 630 may generally surround package 2200 between contact surface 412 of processing chip 400 and contact surface 12 of carrier 10 and between contact surface 812 of power chip 810 and contact surface 12 of carrier 10. Underfill 630 may also prevent damage to individual interconnects 910 due to thermal expansion mismatches between carrier 10, interposer 200, processing chip 400, and power IC chip 810. For clarity, underfill 630 may exist surrounding package 2200, within the clearance between package IC chip 100 and the associated topographic feature 30 of carrier 10, between the processing IC chip 400 and carrier 10 surrounding interconnects 910, and between the power IC chip 810 and carrier 10 surrounding interconnects 910.

Cover 650 may be attached to carrier 10 with seal band 660 to cover, encapsulate, or the like, processing chip 400. Generally, during operation of processing chip 400, heat needs to be removed therefrom. In this situation, cover 650 is both a cover and a conduit for heat transfer. As such, thermal interface material 640 may thermally connect the underside surface of cover 650 and the upper surface of adhesive 2004.

FIG. 34 depicts a detailed cross section view of IC package 2300, in accordance with one or more embodiments of the present invention. IC chip 100 is electrically connected to interposer 200 by interconnect 310₁ which is connected to power contact 120 of IC chip 100 and contact 220₁ of interposer 200 and by interconnect 310₂ which is connected to I/O contact 110 of IC chip 100 and contact 220₂ of interposer 200.

Processing IC chip 400 is electrically connected to interposer 200 by a direct connection between contact 420₁ of processing IC chip 400 and contact 2204 of interposer 200. Processing IC chip 400 is electrically connected to carrier 10 by interconnects 910. Processing IC chip 400 may include an electrical path 450 which is electrically connected to contact 420₁.

Power IC chip 810 is electrically connected to interposer 200 by a direct connection between contact 820₂ of power IC chip 810 and contact 220₃ of interposer 200. Power IC chip 810 is electrically connected to carrier 10 by interconnect 910 which is connected to contact 820₁ of power IC chip 810 and contact 20 of carrier 10. Power IC chip 810 may include an electrical path 840 which is electrically connected to contact 820₁ and is electrically connected to contact 820₂.

Interposer 200 may include electrical path 230 and electrical path 240. Path 230, 240 may include various wiring line features as are known in the art. Path 230 may be electrically connected to contact 220₁ and to contact 220₃. Path 240 may be electrically connected to contact 220₂ and to contact 220₄.

To obtain data from the IC chip 100, IC processing chip 400 may send an obtain access instruction or signal by way of path 450 to contact 420₁. The obtain access instruction or signal passes through interposer 200 by path 240 and is received by IC chip 100 at I/O contact 110. In turn, IC chip 100 provides the applicable requested data cached or stored there within IC chip 100 and provides such data to IC processing chip 400 by the same or different electrical path that which was used by IC chip 100 to receive the obtain access instruction. To pass data to the IC chip 100, IC processing chip 400 may send a pass access instruction or signal by way of path 450 to contact 420₁. The pass access instruction or signal passes through interposer 200 by path 240 and is received by IC chip 100 at I/O contact 110. In turn, IC chip 100 caches or stores the data included in the pass access instruction there within. Similarly, source/ground 50, which may be located in carrier 10, as shown in in power IC chip 810, may provide electrical potential or ground, respectively, to a respective power/ground contact 120 IC chip 100 by way of path 840, 230.

Generally, the particular metallurgy of various interconnects 310, 510, 610, 910, 1210, or the like, may be chosen depending upon the assembly order or assembly process utilized to connect the associated different devices together. For example, microbump interconnects may have a higher melt temperature than C4 type interconnects, etc, so as not to reflow the microbump interconnects during C4 join.

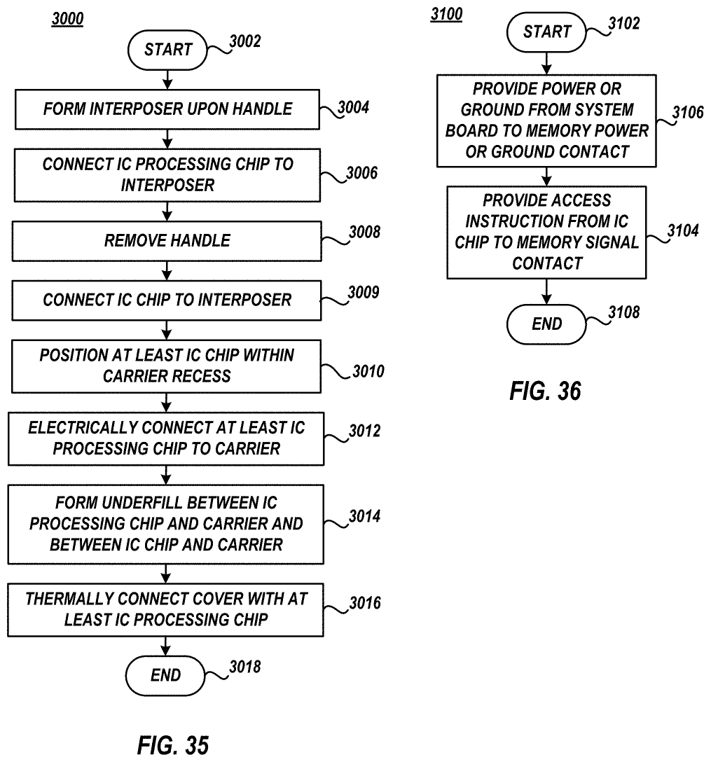

FIG. 35 depicts an exemplary IC package fabrication flow method 3000, in accordance with one or more embodiments of the present invention. Method 3000 begins at block 3002 and continues with forming interposer 200 upon handle 250 (block 3004). Method 3000 may continue by connecting IC processing chip 400 to interposer 200 with interconnects 510 (block 3006). For example, interconnects 510 are positioned upon contacts 220 of interposer 200 and processing IC chip 400 is positioned such that its contacts 420 are upon interconnects 510.

Method 3000 may continue with removing handle 250 (block 3008) and forming contacts 220 upon the surface of interposer 200 from which the handle 250 was removed. Method 3000 may continue with connecting IC chip 100 to interposer 200 (block 3009). For example, interconnects 310 are positioned upon contacts 220 of interposer 200 and IC chip 100 is positioned such that its contacts 110, 120 are upon interconnects 310. Method 3000 may continue with forming underfill surrounding contacts 110, 120, etc. between a structure or structures above such contacts and a structure or structures below such contacts.

Method 3000 may continue with positioning the processing chip 400, interposer 200, and IC chip 100 package upon carrier 10 such that at least IC chip 100 is positioned within a topographic recess feature of carrier 10 (block 3010). For example, at least carrier facing surface 102 of IC chip 100 is between the chip facing surface 12 of carrier 10 and chip facing surface 32 of topographic feature 30, or the like.

Method 3000 may continue with electrically connecting at least the IC processing chip 400 to carrier 10 (block 3012). For example, interconnects 610 are positioned upon contacts 20 of carrier 20 and IC processing chip 400 is positioned such that its contacts 420 are upon interconnects 610.

Method 3000 may continue by forming underfill between processing IC chip 400 and carrier 10 and between IC chip 100 and carrier 10 (block 3212). For example, underfill 630 between processing IC chip 400 and carrier 10 and between IC chip 100 and carrier 10.

Method 3000 may continue with thermally connecting cover 650 with the processing IC chip 400 (block 3016). For example, thermal interface 640 is applied to the top surface of IC processing chip 400 and a seal band is applied around the perimeter of the seating area of the particular IC package upon carrier 10. Cover 650 is attached to the particular IC package by contacting thermal interface 640 and seal band 660.

FIG. 36 depict an exemplary method 3100 of accessing, providing power potential, and/or ground potential to IC chip 100, in accordance with one or more embodiments of the present invention. Method 3100 begins at block 3102 and continues with a potential or current source 50 providing power/ground potential to memory IC package power contact 120 (block 3106). The element 50 may be within carrier 10, power IC chip 800, or within a system or mother board that which is connected to the carrier 10 on the opposite side of carrier 10 that which is connected to processing IC chip 400. For example, the potential or current from element 50 is received at interposer 200 and is routed to IC chip 100 power contact 120 via path 230. In some embodiments, path 230 may also provide the potential or current to processing IC chip 400.

Method 3100 may continue with the processing IC chip 400 providing an access obtain or access provide signal or instruction to IC chip 100 I/O contact 110 (block 3104). For example, processing IC chip 400 sends the a read or write signal or instruction upon path 450 to interposer 200 and interposer 200 routes the access signal or instruction upon path 240 to contact 110.

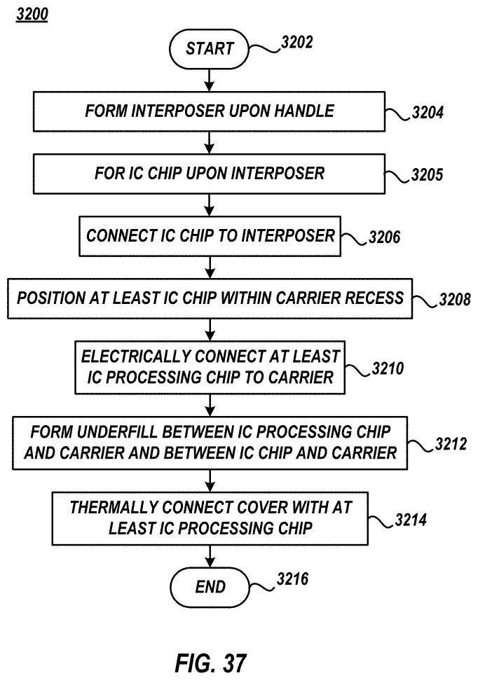

FIG. 37 depicts an exemplary IC package fabrication flow method 3200, in accordance with one or more embodiments of the present invention. Method 3200 begins at block 3202 and continues with forming interposer 200 upon handle 250 (block 3204). For example, a interposer 200 layer is formed upon handle 250, contact trenches are formed therewith and wiring and/or contacts are formed within the trenches. Such build up process may be repeated to form the interposer 200.

Method 3200 may continue with forming or connecting IC chip 100 to interposer 200 (block 3205). For example, an interconnect 310 may connect a power/ground contact 120 with a contact 220 and another interconnect 310 may connect an I/O contact 110 with a contact 220, respectively.

Method 3200 may continue with connecting IC chip 100 to interposer 200 (block 3206). For example, an interconnect 310 is formed or applied to contacts 220 of interposer 200. Power contact 120, ground contact 120, and signal contact 110 of IC chip 100 is positioned upon a respective interconnect 310 to electrically connect the IC chip 100 to interposer 200.

Method 3200 may continue with positioning at least the IC chip 100 within a topographic recess feature of carrier 10 (block 3208). For example, at least carrier facing surface 102 of IC chip 100 is positioned between the chip facing surface 12 of carrier 10 and chip facing surface 32 of topographic feature 30, or the like.

Method 3200 may continue with electrically connecting at least the IC processing chip 400 to carrier 10 (block 3210). For example, interconnects 610 are positioned upon contacts 20 of carrier 20 and IC processing chip 400 is positioned such that its contacts 420 are upon interconnects 610. In some embodiments, method 3200 may continue with electrically connecting interposer 200 to carrier 10.

Method 3200 may continue by forming underfill between processing IC chip 400 and carrier 10 and between IC chip 100 and carrier 10 (block 3212). For example, underfill 630 between processing IC chip 400 and carrier 10 and between IC chip 100 and carrier 10.

Method 3200 may continue with thermally connecting cover 650 with the processing IC chip 400 (block 3214). For example, thermal interface 640 is applied to the top surface of IC processing chip 400 and a seal band is applied around the perimeter of the seating area of the particular IC package upon carrier 10. Cover 650 is attached to the particular IC package by contacting thermal interface 640 and seal band 660.

For clarity, features depicted in one FIG. may be included in embodiments depicted in other FIGs, as appropriate. For example, mold 430 may be included in those embodiments in which mold 430 is not depicted in the Figures, such as FIG. 16-FIG. 30, and the like.

For clarity, IC chip 100 and processing IC chip 400 are generally different types of IC chips. For example, IC chip 100 may be a memory IC chip and processing IC chip 400 may be a processor.

Further for clarity, the order of the blocks does not reflect a sequential order as performance of such features may occur out of order, as appropriate.

The accompanying figures and this description depicted and described embodiments of the present invention, and features and components thereof. Those skilled in the art will appreciate that any particular nomenclature used in this description was merely for convenience, and thus the invention should not be limited by the specific process identified and/or implied by such nomenclature. Therefore, it is desired that the embodiments described herein be considered in all respects as illustrative, not restrictive, and that reference be made to the appended claims for determining the scope of the invention.

The exemplary methods and techniques described herein may be used in the fabrication of integrated circuit chip packages. The chip package may be integrated with other chips, discrete circuit elements and/or other signal processing devices as part of either (a) an intermediate product, such as a motherboard, or (b) an end product. The end product can be any product that includes integrated circuit chips, ranging from toys and other low-end applications to advanced computer products having numerous components, such as a display, a keyboard or other input device and/or a central processor, as non-limiting examples.

References herein to terms such as “vertical”, “horizontal”, etc. are made by way of example, and not by way of limitation, to establish a frame of reference. The term “horizontal” as may be used herein is defined as a plane parallel to the conventional plane or surface 12 of carrier 10, regardless of the actual spatial orientation of the carrier 10. The term “vertical” refers to a direction perpendicular to the horizontal, as just defined. Terms, such as “on”, “above”, “below”, “side” (as in “sidewall”), “higher”, “lower”, “over”, “beneath,” “under”, “top,” “bottom,” “left,” “right,” or the like, are used with respect to the horizontal plane. It is understood that various other frames of reference may be employed for describing the present invention without departing from the spirit and scope of the present invention.

1. A method of integrated circuit (IC) package fabrication comprising:
forming a heterogeneous IC chip interposer upon a handle;
joining a contact surface of a first IC chip to a chip facing surface of the heterogeneous IC chip interposer;
removing the handle to expose a carrier facing surface of the heterogeneous IC chip interposer, wherein the carrier facing surface opposes the chip facing surface;
joining a contact surface of a second IC chip to the carrier facing surface of the heterogeneous IC chip interposer;
after joining the contact surface of the second IC chip to the heterogenous IC chip interposer, positioning the second IC chip within a topographic recess of a carrier such that a clearance exists between the second IC chip and the topographic recess of the carrier and positioning the heterogeneous IC chip interposer between the first IC chip and the carrier; and
joining the carrier facing surface of the heterogenous IC chip interposer with the carrier.

2. The method of claim 1, wherein positioning the second IC chip within the topographic recess of the carrier comprises:
positioning a carrier facing surface of the second IC chip between a first IC chip facing surface of the carrier and a first IC chip facing surface of the topographic recess.

3. (canceled)

4. The method of claim 1, further comprising:
forming a mold around the circumference of the first IC chip and upon the heterogenous IC chip interposer.

5. The method of claim 1, wherein joining the contact surface of the second IC chip to the carrier facing surface of the heterogenous IC chip interposer comprises:
electrically connecting an IC chip power contact and a first heterogenous IC chip interposer contact with a first interconnect; and
electrically connecting an IC chip signal contact and a second heterogenous IC chip interposer contact with a second interconnect.

6. The method of claim 4, wherein joining the contact surface of the first processing IC chip to the first chip facing surface of the heterogenous IC chip interposer comprises:
electrically connecting a first contact of the first IC chip and a third heterogenous IC chip interposer contact with a third interconnect.

7. The method of claim 1, wherein the first IC chip is a processing IC chip and wherein the second IC chip is a memory IC chip.

8.-20. (canceled)

21. The method of claim 6, wherein joining the contact surface of the first IC chip to the chip facing surface of the heterogeneous IC chip interposer comprises:
forming a first underfill between the contact surface of the first IC chip and the chip facing surface of the heterogeneous IC chip interposer and surrounding the third interconnect.

22. The method of claim 21, wherein joining the contact surface of the second IC chip to the carrier facing surface of the heterogenous IC chip interposer comprises:
forming a second underfill between the contact surface of the second IC chip and the carrier facing surface of the heterogenous IC chip interposer, surrounding the first interconnect, and surrounding the second interconnect.

23. The method of claim 22, wherein the first underfill is further internal to the mold.

24. The method of claim 23, further comprising:
joining the carrier facing surface of the heterogenous IC chip interposer to the carrier.

25. The method of claim 24, wherein joining the carrier facing surface of the heterogenous IC chip interposer to the carrier comprises:
electrically connecting a contact of the carrier and a fourth heterogenous IC chip interposer contact with a fourth interconnect.

26. The method of claim 25, further comprising:
forming a fourth underfill between the carrier and the carrier facing surface of the heterogenous IC chip interposer surrounding the fourth interconnect and within the clearance between the second IC chip and the topographic recess.

27. The method of claim 26, wherein the fourth underfill is further formed upon one or more sidewalls of the heterogenous IC chip interposer.

28. The method of claim 27, wherein the fourth underfill is further formed upon one or more sidewalls of the mold.

29. The method of claim 24, further comprising:
connecting a cover to the first IC chip and to the carrier.

30. The method of claim 29, wherein connecting the cover to the first IC chip and to the carrier comprises:
joining the cover to the first IC chip with a thermal interface material; and
joining the cover to the carrier with a seal band.

31. The method of claim 30, wherein connecting the cover to the first IC chip and to the carrier further comprises:
joining the cover to the mold with the thermal interface material.

32. The method of claim 4, where an upper surface of the first IC chip is coplanar with an upper surface of the mold.
